(19) United States
(12) Patent Application Publication
(10) Pub. No.: US 2026/0018550 A1
(43) Pub. Date: Jan. 15, 2026

(54) STRUCTURE AND METHOD FOR FABRICATING THE STRUCTURE

(71) Applicant: TAIWAN SEMICONDUCTOR MANUFACTURING COMPANY, LTD., Hsinchu (TW)

(72) Inventors: Huang-Yu CHEN, Hsinchu County (TW); Min-Feng HUNG, Changhua City (TW); Hsin-Ying LIN, Tainan City (TW); Ching-Fang CHEN, Taichung City (TW); Chih-Wei CHANG, New Taipei City (TW)

(73) Assignee: TAIWAN SEMICONDUCTOR MANUFACTURING COMPANY, LTD., Hsinchu (TW)

(21) Appl. No.: 18/767,851

(22) Filed: Jul. 9, 2024

(51) Int. Cl. H01L 23/00; H01L 23/495; H01L 23/522

(52) U.S. Cl. CPC H01L 24/14; H01L 23/4952; H01L 23/5226; H01L 2224/1403; H01L 2224/14177; H01L 2924/381

(57) ABSTRACT

A structure includes at least one ball, at least one bump and at least one route. The at least one route is configured to couple the at least one ball to the at least one bump. The at least one route comprises a plurality of first route edges and a plurality of second route edges, and an angle between one of plurality of first route edges and one of plurality of second route edges is approximately equal to an angle between another one of plurality of first route edges and another one of plurality of second route edges.

### BACKGROUND

Substrate designs are challenging with route planning of redistribution layers (RDL) in limited number of layers in order to meet electrical and physical constraints. Some electronic design automation (EDA) routers route all nets directly. However, sequential net-by-net routing often results in poor routing quality. In addition, routing manually leads to lack of efficiency.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1D are schematic diagrams of a semiconductor device corresponding to a method including operations, in accordance with some embodiments of the present disclosure.

FIG. 1E is a schematic diagram of further detail of the bundle route, in accordance with some embodiments of the present disclosure.

FIG. 1F is a schematic diagram of a semiconductor device corresponding to the semiconductor device shown in FIG. 1D, in accordance with some embodiments of the present disclosure.

FIG. 2A to FIG. 2C are schematic diagrams of a semiconductor device corresponding to a method including operations, in accordance with some embodiments of the present disclosure.

FIG. 3A is a schematic diagram of the semiconductor device corresponding to a method including an operation, in accordance with some embodiments of the present disclosure.

FIG. 3B is a schematic diagram of the semiconductor device corresponding to a method including an operation, in accordance with some embodiments of the present disclosure.

FIG. 4A to FIG. 4E are schematic diagrams of the semiconductor device corresponding to a method including operations, in accordance with some embodiments of the present disclosure.

FIG. 5A to FIG. 5C are schematic diagrams of the semiconductor device corresponding to a method including operations, in accordance with some embodiments of the present disclosure.

FIG. 5D is a schematic diagram of further detail of the bundle route shown in FIG. 5C, in accordance with some embodiments of the present disclosure.

FIG. 6A and FIG. 6B are schematic diagrams of G-cells in the semiconductor device corresponding to a method including operations, in accordance with some embodiments of the present disclosure.

FIG. 7A and FIG. 7B are schematic diagrams of G-cells in the semiconductor device corresponding to a method including operations, in accordance with some embodiments of the present disclosure.

FIG. 8A and FIG. 8B are schematic diagrams of a G-cell in the semiconductor device corresponding to a method including operations, in accordance with some embodiments of the present disclosure.

FIG. 9A to FIG. 9C are schematic diagrams of a semiconductor device corresponding to a method including operations, in accordance with some embodiments of the present disclosure.

FIG. 10A to FIG. 10B are schematic diagrams of a semiconductor device corresponding to a method including operations, in accordance with some embodiments of the present disclosure.

FIG. 11A to FIG. 11D are schematic diagrams of the semiconductor device corresponding to a method including operations, in accordance with some embodiments of the present disclosure.

FIG. 12A to FIG. 12D are schematic diagrams of the G-cells in the semiconductor device corresponding to a method, in accordance with some embodiments of the present disclosure.

FIG. 13A and FIG. 13B are schematic diagrams of the G-cells in the semiconductor device corresponding to a method, in accordance with some embodiments of the present disclosure.

FIG. 14A to FIG. 14C are schematic diagrams of a semiconductor device corresponding to a method including operations, in accordance with some embodiments of the present disclosure.

FIG. 14D is a cross sectional diagram of a structure corresponding to the route structures described above, in accordance with some embodiments of the present disclosure.

FIG. 14E is a flowchart diagram of a method for fabricating the structure shown in FIG. 14D, in accordance with some embodiments of the present disclosure.

FIG. 15A and FIG. 15B are schematic diagrams of the G-cells in the semiconductor device corresponding to a method, in accordance with some embodiments of the present disclosure.

FIG. 15C are schematic diagrams of a congestion map, in accordance with some embodiments of the present disclosure.

FIG. 16A and FIG. 16B are schematic diagrams of the G-cells in the semiconductor device corresponding to a method, in accordance with some embodiments of the present disclosure.

FIG. 17 is a flowchart of a method of routing a semiconductor device in accordance with some embodiments of the present disclosure.

FIG. 18 is a flowchart of a method of routing a semiconductor device in accordance with some embodiments of the present disclosure.

FIG. 19 is a flowchart diagram of a method designing the semiconductor device shown in FIG. 1A, in accordance with some embodiments of the present disclosure.

FIG. 20 is a flowchart diagram of a method designing the semiconductor device shown in FIG. 1A, in accordance with some embodiments of the present disclosure.

FIG. 21 is a block diagram of an electronic design automation (EDA) system for designing the semiconductor device shown in FIG. 1A, in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

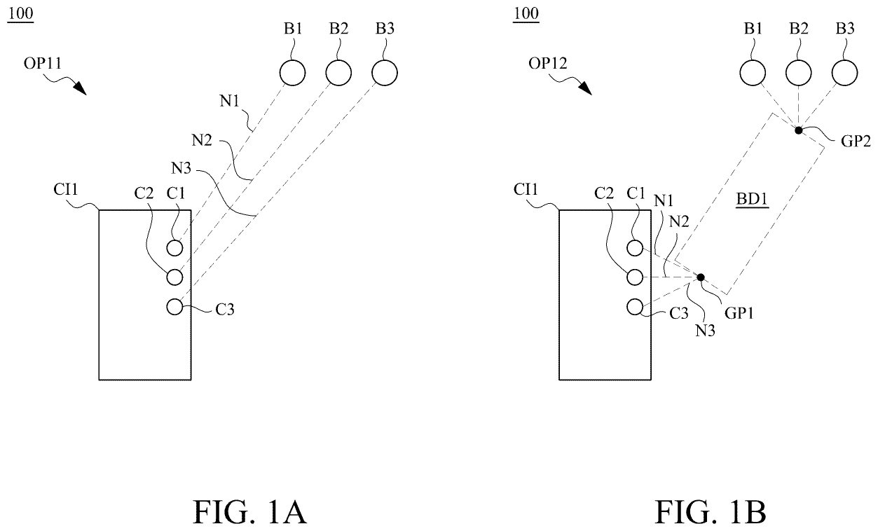

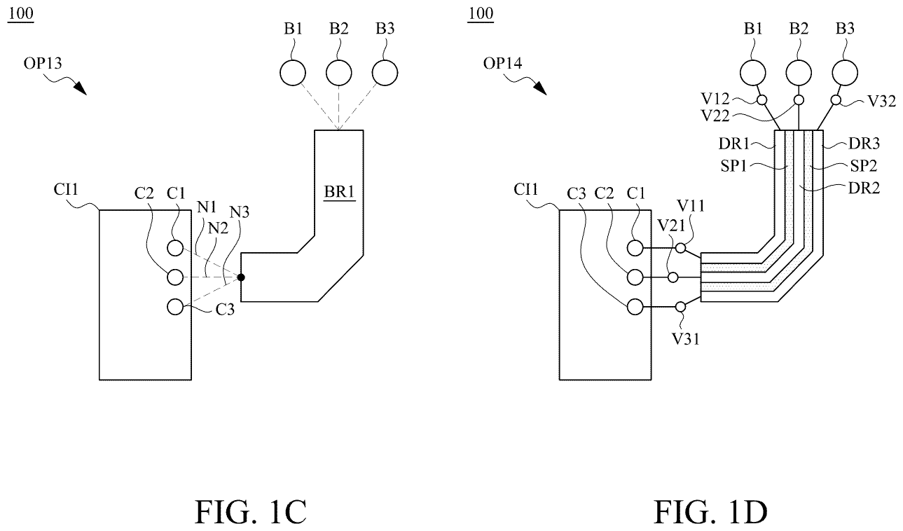

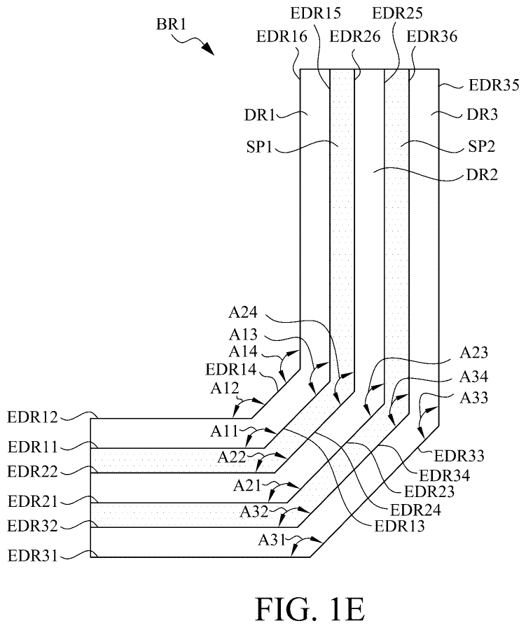

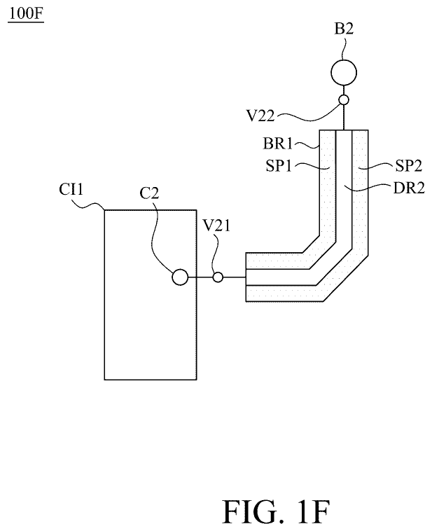

FIG. 1A to FIG. 1D are schematic diagrams of a semiconductor device 100 corresponding to a method including operations OP11-OP14, in accordance with some embodiments of the present disclosure. In some embodiments, the method is performed by an electronic design automation (EDA) tool to route the semiconductor device 100. The operations OP11-OP14 are performed in order. The schematic diagrams shown in FIG. 1A to FIG. 1D correspond to intermediate states of the semiconductor device 100 during a routing process of the method.

As illustrated in FIG. 1A, the semiconductor device 100 includes a circuit CI1, balls B1-B3 and nets N1-N3. The circuit CI1 includes bumps C1-C3. At the operation OP11, bumps and balls are connected through nets. Specifically, the bump C1 is connected to the ball B1 through the net N1. The bump C2 is connected to the ball B2 through the net N2. The bump C3 is connected to the ball B3 through the net N3.

In some embodiments, each of the nets N1-N3 corresponds to a flyline at the operation OP11. A flyline indicates a straight line connected between a bump and a ball. The bumps C1-C3 and the balls B1-B3 are on different layers.

As illustrated in FIG. 1B, the semiconductor device 100 further includes a bundle BD1 and gather points GP1-GP2. At the operation OP12, nets connecting same input/output (I/O) interface or intellectual property (IP) core are grouped into a bundle to route with similar topology and property. Specifically, the nets N1-N3 are grouped into the bundle BD1 from the gather point GP1 to the gather point GP2. In some embodiments, the gather points in a bundle connect pins of nets, such as bumps, balls or vias. Specifically, the gather points GP1 and GP2 in the bundle BD1 connect nets N1-N3. The bundle BD1 is a bundle with three grouped nets, such as nets N1-N3.

As illustrated in FIG. 1B, in some embodiments, the distance between the bump C1 and the gather point GP1, the distance between the bump C2 and the gather point GP1 and the distance between the bump C3 and the gather point GP1 is distance D31 are approximately the same. The distance between the ball B1 and the gather point GP2, the distance between the ball B2 and the gather point GP2, the distance between the ball B3 and the gather point GP2 are approximately the same.

In some embodiments, the nets in the same bundle correspond to the same bus and perform similar functions. Examples of different buses are such as double data rate (DDR) memory byte lanes, serial peripheral interface (SPI) mode, clock (CLK) mode, general purpose input/output (GPIO) mode, peripheral component interconnect express (PCIe) mode, SoundWire (SW) mode, management data input/output (MDIO) mode, DisplayPort (DP) mode and the like.

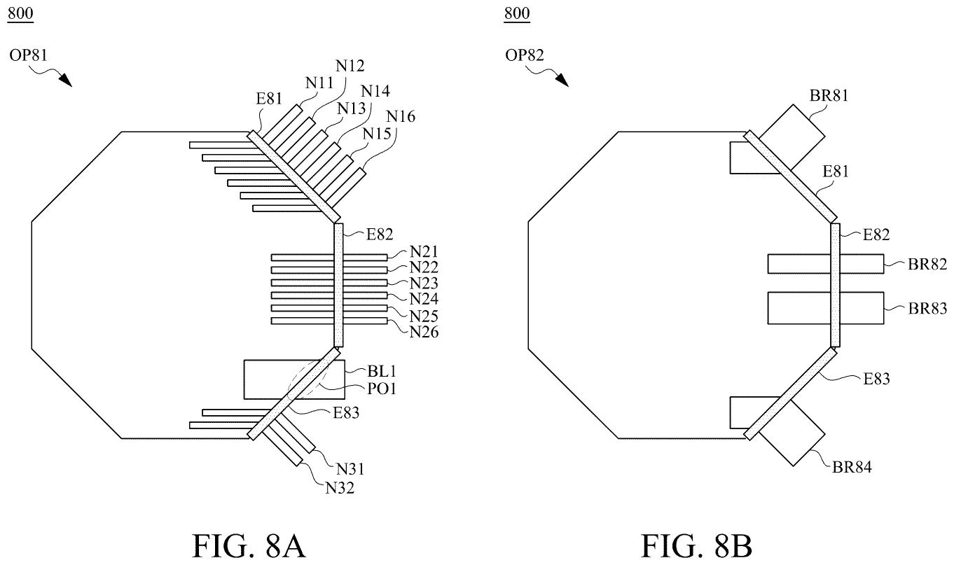

As illustrated in FIG. 1C, the semiconductor device 100 further includes a bundle route BR1 instead of the bundle BD1. At the operation OP13, a bundle is transformed into a bundle route according to at least one global cell (G-cell). Specifically, referring to FIG. 1B and FIG. 1C, the bundle BD1 in FIG. 1B is transformed into the bundle route BR1 in FIG. 1C according to G-cells, such as the G-cell 800 in FIG. 8A and FIG. 8B.

As illustrated in FIG. 1D, the semiconductor device 100 further includes vias V11, V12, V21, V22, V31, V32, routes DR1-DR3 and spaces SP1-SP2 instead of the bundle route BR1. In some embodiments, the bumps C1-C3 are on the same layer, and the balls B1-B3 are on the same layer. The vias V11, V21 and V31 connect bumps C1-C3 to routes DR1-DR3 respectively, and the vias V12, V22 and V32 connect balls B1-B3 to routes DR1-DR3 respectively. In some embodiments, routes are separated from each other by spaces. Specifically, the route DR1 is separated from the route DR2 by the space SP1, and the route DR2 is separated from the route DR3 by the space SP2. Referring to FIG. 1C and FIG. 1D, the routes DR1-DR3 are arranged parallel to each other along the bundle route BR1.

At the operation OP14, a route is generated, connected through vias and guided by the bundle route to electrically connect a bump and a ball. Specifically, the route DR1 is generated, connected through vias V11 and V12 and guided by the bundle route BR1 to electrically connect the bump C1 and the ball B1. The route DR2 is generated, connected through vias V21 and V22 and guided by the bundle route BR1 to electrically connect the bump C2 and the ball B2. The route DR3 is generated, connected through vias V31 and V32 and guided by the bundle route BR1 to electrically connect the bump C3 and the ball B3.

Referring to FIG. 1A to FIG. 1D, in some embodiments, each of a bundle, a bundle route transformed by the bundle and routes transformed by the bundle route is located between bumps and balls corresponding to grouped nets in the bundle. Specifically, each of the bundle BD1, the bundle route BR1 and the routes DR1-DR3 is located between the bumps C1-C3 and the balls B1-B3 corresponding to the nets N1-N3 in the bundle BD1.

FIG. 1E is a schematic diagram of further detail of the bundle route BR1, in accordance with some embodiments of the present disclosure. As illustrated in FIG. 1E, the routes DR1-DR3 are disposed in the bundle route BR1. The route DR1 includes route edges EDR11-EDR16. The route DR2 includes route edges EDR21-EDR26. The route DR3 includes route edges EDR31-EDR36. The route edges EDR11, EDR13, EDR15, EDR21, EDR23, EDR25, EDR31, EDR33 and EDR35 are opposite with the route edges EDR12, EDR14, EDR16, EDR22, EDR24, EDR26, EDR32, EDR34 and EDR36, respectively.

In the embodiment shown in FIG. 1E, the route edges EDR11, EDR12, EDR21, EDR22, EDR31 and EDR32 are approximately parallel with each other and extend along the horizontal direction. The route edges EDR13, EDR14, EDR23, EDR24, EDR33 and EDR34 are approximately parallel with each other and extend along an oblique direction. The route edges EDR15, EDR16, EDR25, EDR26, EDR35 and EDR36 are approximately parallel with each other and extend along the vertical direction.

In some embodiments, an angle A11 between the route edges EDR11 and EDR13, an angle A12 between the route edges EDR12 and EDR14, an angle A21 between the route edges EDR21 and EDR23, an angle A22 between the route edges EDR22 and EDR24, an angle A31 between the route edges EDR31 and EDR33 and an angle A32 between the route edges EDR32 and EDR34 are approximately equal to each other. In some embodiments, each of the angles A11, A12, A21, A22, A31 and A32 is within a range of 90 degrees to 180 degrees.

Similarly, an angle A13 between the route edges EDR15 and EDR13, an angle A14 between the route edges EDR16 and EDR14, an angle A23 between the route edges EDR25 and EDR23, an angle A24 between the route edges EDR26 and EDR24, an angle A33 between the route edges EDR35 and EDR33 and an angle A34 between the route edges EDR36 and EDR34 are approximately equal to each other. In some embodiments, each of the angles A13, A14, A23, A24, A33 and A34 is within a range of 90 degrees to 180 degrees.

In some embodiments, distances between the routes are smaller than widths of the routes. For example, along the vertical direction, a distance between the route edges EDR11 and EDR22 is shorter than or close to each of the widths of the routes DR1-DR3, and a distance between the route edges EDR21 and EDR32 is shorter than or close to each of the widths of the routes DR1-DR3. Along the oblique direction, a distance between the route edges EDR13 and EDR24 is shorter than or close to each of the widths of the routes DR1-DR3, and a distance between the route edges EDR23 and EDR34 is shorter than or close to each of the widths of the routes DR1-DR3. Along the vertical direction, a distance between the route edges EDR15 and EDR26 is shorter than or close to each of the widths of the routes DR1-DR3, and a distance between the route edges EDR25 and EDR36 is shorter than or close to each of the widths of the routes DR1-DR3. In some embodiments, a width of a route is a distance between two route edges of the route.

FIG. 1F is a schematic diagram of a semiconductor device 100F corresponding to the semiconductor device 100 shown in FIG. 1D, in accordance with some embodiments of the present disclosure. Referring to FIG. 1F and FIG. 1D, the semiconductor device 100F is an alternative embodiment of the semiconductor device 100. FIG. 1F follows a similar labeling convention to that of FIG. 1D. For brevity, the discussion will focus more on differences between FIG. 1F and FIG. 1D than on similarities.

Compared to the semiconductor device 100, in the semiconductor device 100F, the bundle route BR1 only contains one route DR2 instead of containing the three routes DR1-DR3. Alternatively stated, a second route is not necessarily required to be contained in the bundle route BR1.

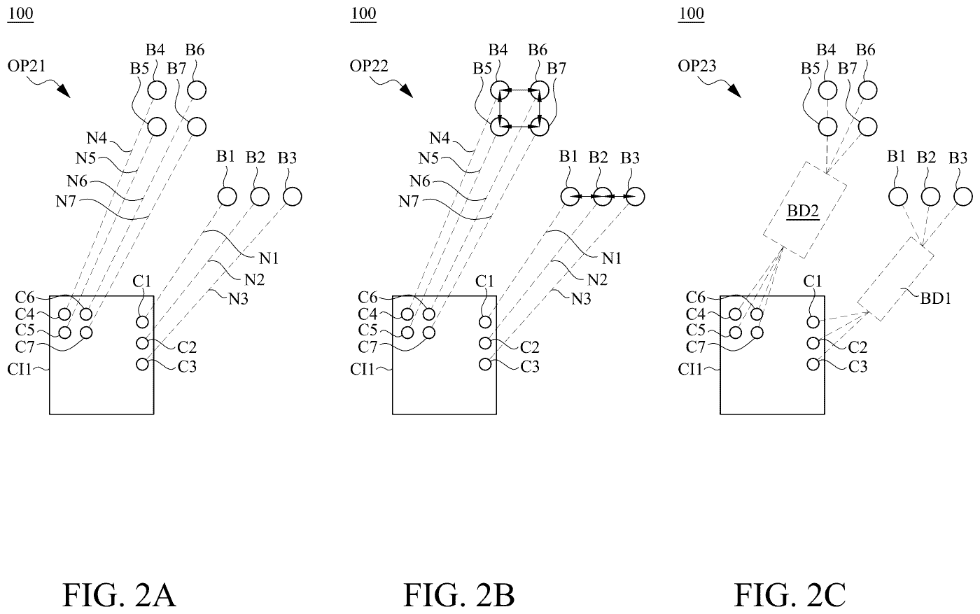

FIG. 2A to FIG. 2C are schematic diagrams of a semiconductor device 100 corresponding to a method including operations OP21-OP23, in accordance with some embodiments of the present disclosure. In some embodiments, the method is performed by the EDA tool to route the semiconductor device 100. The operations OP21-OP23 are performed in order. The schematic diagrams shown in FIG. 2A to FIG. 2C correspond to intermediate states of the semiconductor device 100 during a routing process of the method.

As illustrated in FIG. 2A, the semiconductor device 100 includes the circuit CI1, balls B1-B7 and nets N1-N7. The circuit CI1 includes bumps C1-C7. At the operation OP21, bumps and balls are connected through nets. Specifically, the bumps C1-C7 are connected to the balls B1-B7 through the nets N1-N7. In some embodiments, each of the nets N1-N7 corresponds to a flyline. The bumps C1-C7 and the balls B1-B7 are on different layers.

As illustrated in FIG. 2B, at the operation OP22, nets are grouped by pin proximity. Specifically, nets corresponding to pins with smaller distance between each other are grouped together. For example, distances between the bumps C1-C3 are smaller than distances between the bumps C1-C3 and C4-C7, distances between the bumps C4-C7 are smaller than distances between the bumps C1-C3 and C4-C7, distances between the balls B1-B3 are smaller than distances between the balls B1-B3 and B4-B7, and distances between the balls B4-B7 are smaller than distances between the balls B1-B3 and B4-B7. Accordingly, nets N1-N3 are grouped together as a first group, and nets N4-N7 are grouped together as a second group. In some embodiments, a pin is implemented by a bump, a ball or a via.

For another example, each of a distance between the bumps C1 and C2 and a distance between the bumps C1 and C3 is smaller than each of a distance between the bumps C1 and C4, a distance between the bumps C1 and C5, a distance between the bumps C1 and C6 and a distance between the bumps C1 and C7, and each of a distance between the balls B1 and B2 and a distance between the balls B1 and B3 is smaller than each of a distance between the balls B1 and B4, a distance between the balls B1 and B5, a distance between the balls B1 and B6 and a distance between the balls B1 and B7. Accordingly, the net N1 is grouped together with the nets N2 and N3 as the first group.

For another example, each of a distance between the bumps C4 and C5, a distance between the bumps C4 and C6 and a distance between the bumps C4 and C7 is smaller than each of a distance between the bumps C4 and C1, a distance between the bumps C4 and C2, a distance between the bumps C4 and C3, and each of a distance between the balls B4 and B5, a distance between the balls B4 and B6 and a distance between the balls B4 and B7 is smaller than each of a distance between the balls B4 and B1, a distance between the balls B4 and B2, a distance between the balls B4 and B3. Accordingly, the net N4 is grouped together with the nets N5-N7 as the second group.

In some embodiments, also at the operation OP22, nets are grouped by logical. Specifically, when the nets belong to the same bus or constraints, such as a match group or a differential pair, the nets are grouped together. In some embodiments, nets in the same bus perform similar functions.

In some embodiments, also at the operation OP22, nets are grouped and configurable by users. Specifically, users group the nets through adding, removing, splitting or merging the nets according to the preferences of the designers.

As illustrated in FIG. 2C, the semiconductor device 100 further includes bundles BD1 and BD2. At the operation OP23, bundles are created according to the grouped nets. Specifically, nets N1-N3 are grouped into the bundle BD1 according to the first group, and nets N4-N7 are grouped into the bundle BD2 according to the second group.

In some embodiments, after the bundles BD1 and BD2 are created, the bundles BD1 and BD2 are transformed into bundle routes BR1 and BR2 according to the G-cells, respectively. After the bundle routes BR1 and BR2 are created, routes DR1-DR7 are generated, connected through vias and guided by the bundle routes BR1-BR2 to electrically connect the bumps C1-C7 and the balls B1-B7.

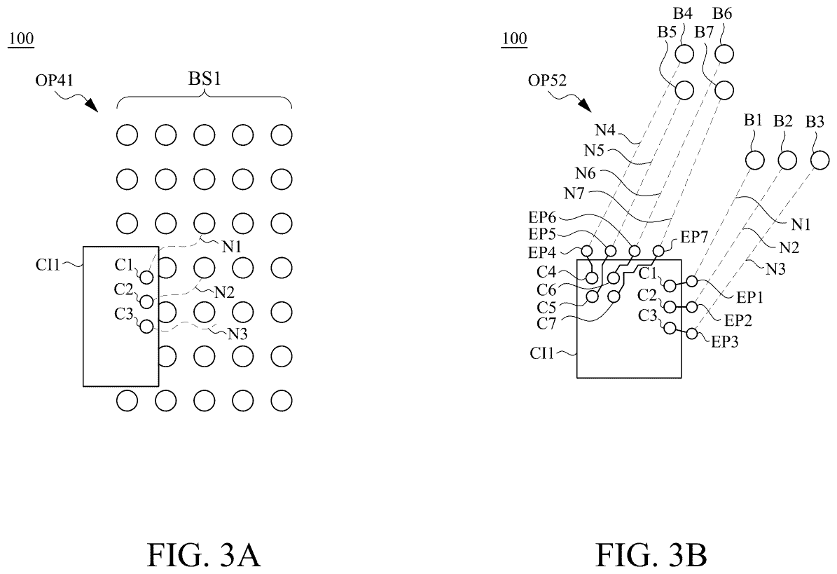

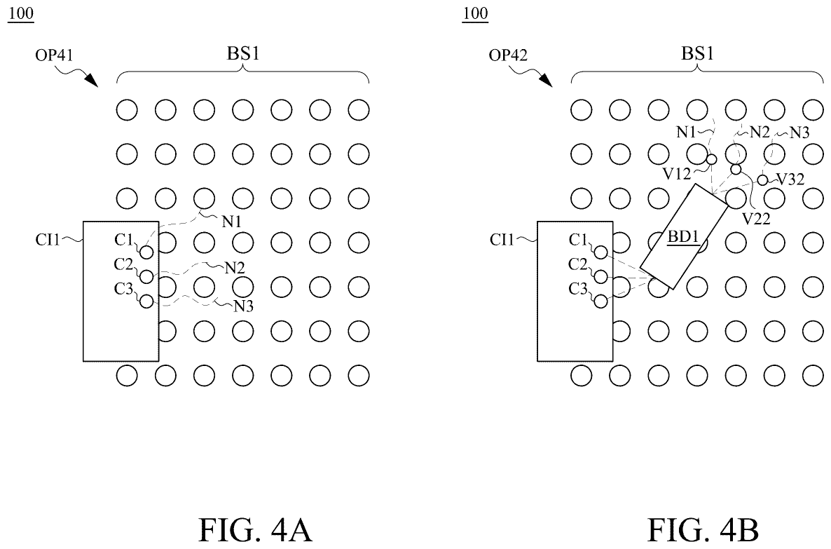

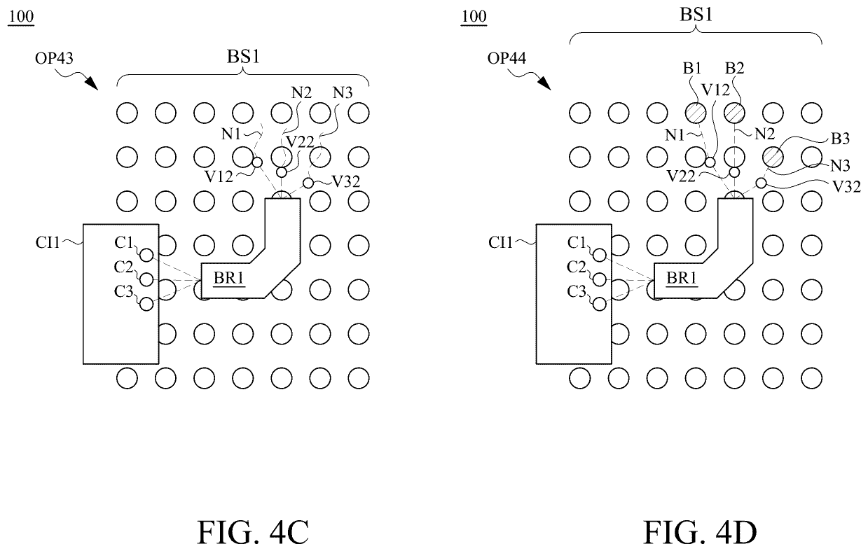

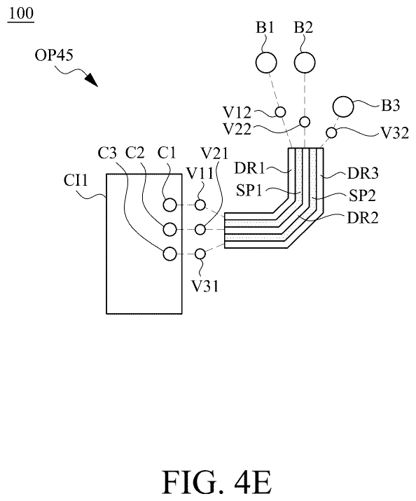

FIG. 3A is a schematic diagram of the semiconductor device 100 corresponding to a method including an operation OP41, in accordance with some embodiments of the present disclosure. In some embodiments, the method is performed by the EDA tool to route the semiconductor device 100. The schematic diagram shown in FIG. 3A corresponds to an intermediate state of the semiconductor device 100 during a routing process of the method. FIG. 3A follows a similar labeling convention to that of FIG. 4A. Therefore, further details regarding the operation OP41 illustrated in FIG. 3A are discussed in FIG. 4A.

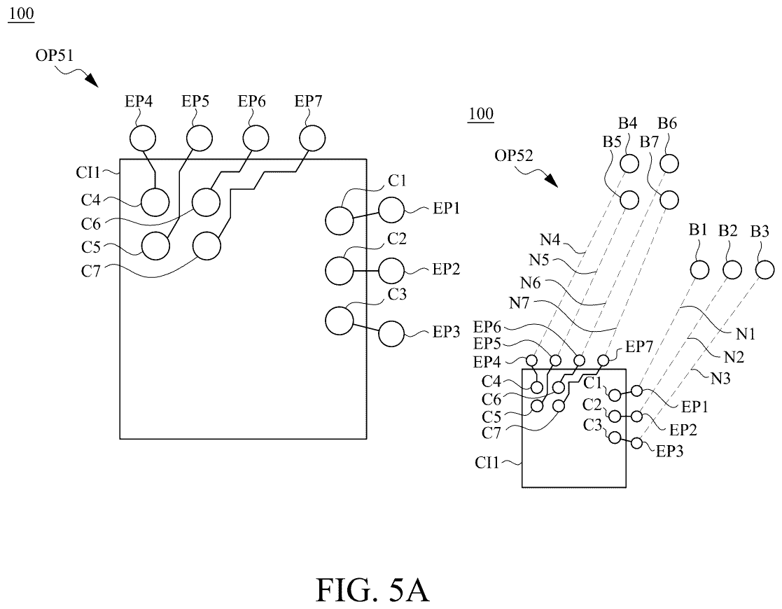

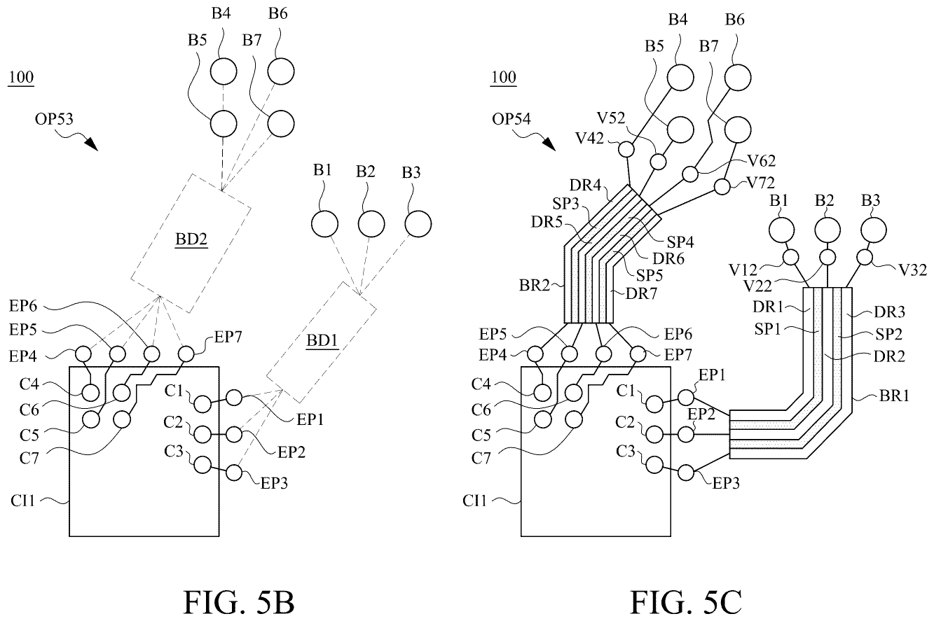

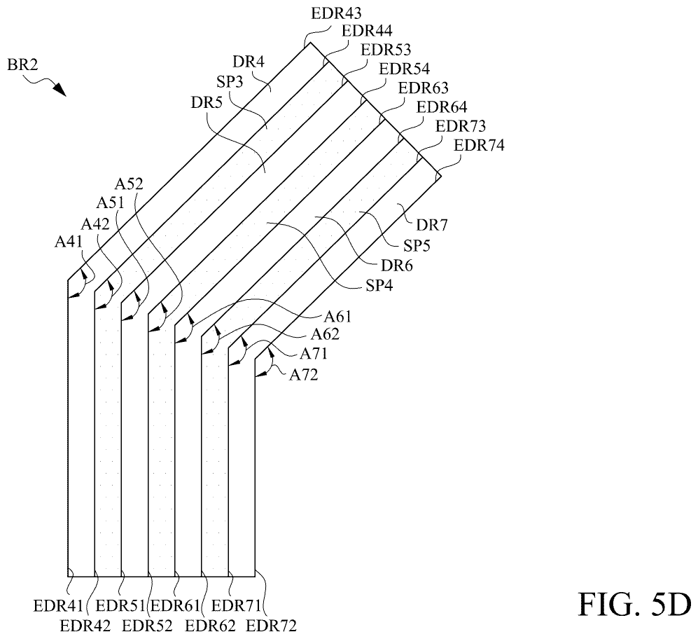

FIG. 3B is a schematic diagram of the semiconductor device 100 corresponding to a method including an operation OP52, in accordance with some embodiments of the present disclosure. In some embodiments, the method is performed by the EDA tool to route the semiconductor device 100. The schematic diagram shown in FIG. 3B corresponds to an intermediate state of the semiconductor device 100 during a routing process of the method. FIG. 3B follows a similar labeling convention to that of FIG. 5A. Therefore, further details regarding the operation OP52 illustrated in FIG. 3B are discussed in FIG. 5A.

Referring to FIG. 3A and FIG. 3B, in some embodiments, a bundle route is flexible for connection in different design phases to meet variable design requirements. Specifically, the operation OP41 corresponds to a design phase that balls are located without assigned nets, and the operation OP52 corresponds to a design phase that bumps are with escape routes in a component. In some embodiments, the design phase corresponds to the routing process. An escape route connects a bump to an escape point.

FIG. 4A to FIG. 4E are schematic diagrams of the semiconductor device 100 corresponding to a method including operations OP41-OP45, in accordance with some embodiments of the present disclosure. In some embodiments, the method is performed by the EDA tool to route the semiconductor device 100. The operations OP41-OP45 are performed in order. The schematic diagrams shown in FIG. 4A to FIG. 4E correspond to intermediate states of the semiconductor device 100 during a routing process of the method.

As illustrated in FIG. 4A, the semiconductor device 100 includes the circuit CI1, nets N1-N3 and balls BS1. The circuit CI1 includes the bumps C1-C3. At the operation OP41, nets are assigned to bumps. Specifically, the nets N1-N3 are assigned to the bumps C1-C3, respectively.

As illustrated in FIG. 4B, the semiconductor device 100 further includes the vias V12, V22, V32 and a bundle BD1. At the operation OP42, bumps and given vias are connected by a bundle. Specifically, the bumps C1-C3 and the vias V12, V22, V32 are connected by the bundle BD1 through the nets N1-N3.

As illustrated in FIG. 4C, the semiconductor device 100 further includes a bundle route BR1 instead of the bundle BD1. At the operation OP43, the bundle is routed to generate a bundle route. Specifically, referring to FIG. 4B and FIG. 4C, the bundle BD1 in FIG. 4B is transformed into the bundle route BR1 in FIG. 4C according to G-cells, such as the G-cell 800 in FIG. 8A and FIG. 8B.

As illustrated in FIG. 4D, the semiconductor device 100 further includes the balls B1-B3. The balls BS1 include at least the balls B1-B3. At the operation OP44, nets are assigned to balls. Specifically, the nets N1-N3 are connected to the balls B1-B3 of the balls BS1, respectively. Accordingly, the bumps C1-C3 are connected to the balls B1-B3 through the nets N1-N3.

As illustrated in FIG. 4E, the semiconductor device 100 further includes the vias V11, V21, V31, routes DR1-DR3 and spaces SP1-SP2 instead of the bundle route BR4. At the operation OP45, routes are generated along the bundle route. Specifically, the routes DR1-DR3 are generated along the bundle route BR1.

Referring to FIG. 4A to FIG. 4E, in some embodiments, in an early design phase, balls do not have assigned nets, and designers will insert vias for route planning, such as plating through hole (PTH). Therefore, bundles can connect bumps and vias to complete routing.

Referring to FIG. 1A to FIG. 1D and FIG. 4A to FIG. 4E, in some embodiments, the operation OP41 corresponds to the operation OP11, the operation OP42 corresponds to the operation OP12, the operations OP43-OP44 correspond to the operation OP13, and the operation OP45 corresponds to the operation OP14.

FIG. 5A to FIG. 5C are schematic diagrams of the semiconductor device 100 corresponding to a method including operations OP51-OP54, in accordance with some embodiments of the present disclosure. In some embodiments, the method is performed by the EDA tool to route the semiconductor device 100. The operations OP51-OP54 are performed in order. The schematic diagrams shown in FIG. 5A to FIG. 5C correspond to intermediate states of the semiconductor device 100 during a routing process of the method.

As illustrated in FIG. 5A, the semiconductor device 100 includes the circuit CI1, escape points EP1-EP7, the balls B1-B7 and the nets N1-N7. The circuit CI1 includes bumps C1-C7. At the operation OP51, bumps are connected to escape points. Specifically, the bumps C1-C7 in the circuit CI1 are connected to the escape points EP1-EP7 through thin lines, respectively. In some embodiments, the thin lines connecting the bumps to the escape points are implemented by conductive materials, such as metal lines.

At the operation OP52, escape points and balls are connected through nets. Specifically, the escape points EP1-EP7 and the balls B1-B7 are connected through the nets N1-N7, respectively. In some embodiments, each of the nets N1-N7 corresponds to a flyline at the operation OP52.

As illustrated in FIG. 5B, the semiconductor device 100 further includes the bundles BD1 and BD2. At the operation OP53, bundles are created. Specifically, bundles BD1 and BD2 are created, the nets N1-N3 are grouped into the bundle BD1, and the nets N4-N7 are grouped into the bundle BD2. Referring to FIG. 5B, FIG. 2B and FIG. 2C, in some embodiments, the bundles BD1 and BD2 are created by the operations OP22 and OP23.

As illustrated in FIG. 5C, the semiconductor device 100 further includes vias V12, V22, V32, V42, V52, V62, V72, bundle routes BR1 and BR2, routes DR1-DR7 and spaces SP1-SP5 instead of the bundles BD1 and BD2. The escape points EP1-EP7 are electrically connected to the vias V12, V22, V32, V42, V52, V62 and V72 by the routes DR1-DR7, respectively. The balls B1-B7 are electrically connected to the vias V12, V22, V32, V42, V52, V62 and V72 by the routes DR1-DR7, respectively. Each of the routes DR1-DR7 is separated from each other. Specifically, the route DR1 is separated from the route DR2 by the space SP1, the route DR2 is separated from the route DR3 by the space SP2, the route DR4 is separated from the route DR5 by the space SP3, the route DR5 is separated from the route DR6 by the space SP4, the route DR6 is separated from the route DR7 by the space SP5.

At the operation OP54, routes are generated, connected by vias and guided by the bundle routes transformed by the bundle to electrically connect bumps and balls. Specifically, referring to FIG. 5B and FIG. 5C, the bundles BD1 and BD2 in FIG. 5B are transformed into the bundle routes BR1 and BR2 in FIG. 5C, respectively, according to G-cells, such as the G-cell 800 in FIG. 8A and FIG. 8B. And then, the route DR1 is generated, connected by the escape point EP1, the via V12 and guided by the bundle route BR1 to electrically connect the bump C1 and the ball B1. The route DR2 is generated, connected by the escape point EP2, the via V22 and guided by the bundle route BR2 to electrically connect the bump C2 and the ball B2. The route DR3 is generated, connected by the escape point EP3, the via V32 and guided by the bundle route BR3 to electrically connect the bump C3 and the ball B3. The route DR4 is generated, connected by the escape point EP4, the via V42 and guided by the bundle route BR4 to electrically connect the bump C4 and the ball B4. The route DR5 is generated, connected by the escape point EP5, the via V52 and guided by the bundle route BR5 to electrically connect the bump C5 and the ball B5. The route DR6 is generated, connected by the escape point EP6, the via V62 and guided by the bundle route BR6 to electrically connect the bump C6 and the ball B6. The route DR7 is generated, connected by the escape point EP7, the via V72 and guided by the bundle route BR7 to electrically connect the bump C7 and the ball B7.

Referring to FIG. 5A to FIG. 5C, in some embodiments, bumps in a component is pin escaped to escape points, such as fanout vias. Then, bundles are created for connection. A gather point of a bundle directly connects to escape points of the component.

FIG. 5D is a schematic diagram of further detail of the bundle route BR2 shown in FIG. 5C, in accordance with some embodiments of the present disclosure. As illustrated in FIG. 5D, the routes DR4-DR7 are disposed in the bundle route BR2. The route DR4 includes route edges EDR41-EDR44. The route DR5 includes route edges EDR51-EDR54. The route DR6 includes route edges EDR61-EDR64. The route DR7 includes route edges EDR71-EDR74. The route edges EDR41, EDR43, EDR51, EDR53, EDR61, EDR63, EDR71 and EDR73 are opposite with the route edges EDR42, EDR44, EDR52, EDR54, EDR62, EDR64, EDR72 and EDR74, respectively.

In the embodiment shown in FIG. 5D, the route edges EDR41, EDR42, EDR51, EDR52, EDR61, EDR62, EDR71 and EDR72 are approximately parallel with each other and extend along the vertical direction. The route edges EDR43, EDR44, EDR53, EDR54, EDR63, EDR64, EDR73 and EDR74 are approximately parallel with each other and extend along an oblique direction.

In some embodiments, an angle A41 between the route edges EDR41 and EDR43, an angle A42 between the route edges EDR42 and EDR44, an angle A51 between the route edges EDR51 and EDR53, an angle A52 between the route edges EDR52 and EDR54, an angle A61 between the route edges EDR61 and EDR63, an angle A62 between the route edges EDR62 and EDR64, an angle A71 between the route edges EDR71 and EDR73 and an angle A72 between the route edges EDR72 and EDR74 are approximately equal to each other. In some embodiments, each of the angles A41, A42, A51, A52, A61, A62, A71 and A72 is within a range of 90 degrees to 180 degrees.

In some embodiments, distances between the routes are smaller than or close to widths of the routes. For example, along the horizontal direction, a distance between the route edges EDR42 and EDR51 is shorter than or close to each of the widths of the routes DR4-DR7, a distance between the route edges EDR52 and EDR61 is shorter than or close to each of the widths of the routes DR4-DR7, and a distance between the route edges EDR62 and EDR71 is shorter than or close to each of the widths of the routes DR4-DR7. Along the oblique direction, a distance between the route edges EDR44 and EDR53 is shorter than or close to each of the widths of the routes DR4-DR7, a distance between the route edges EDR54 and EDR63 is shorter than or close to each of the widths of the routes DR4-DR7, and a distance between the route edges EDR64 and EDR73 is shorter than or close to each of the widths of the routes DR4-DR7.

Referring to FIG. 2A to FIG. 2C and FIG. 5A to FIG. 5C, in some embodiments, the operation OP52 corresponds to the operation OP21, the operation OP53 corresponds to the operation OP23.

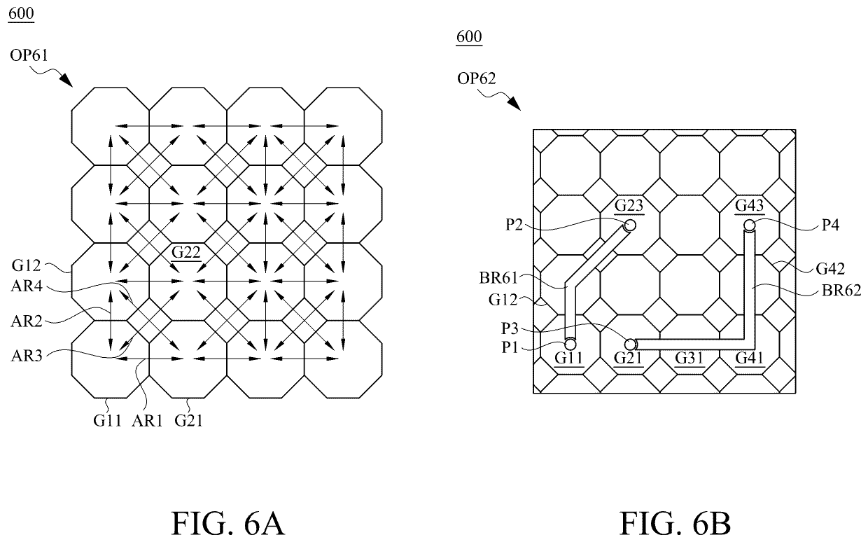

FIG. 6A and FIG. 6B are schematic diagrams of G-cells 600 in the semiconductor device 100 corresponding to a method including operations OP61 and OP62, in accordance with some embodiments of the present disclosure. In some embodiments, the method is performed by the EDA tool to route the semiconductor device 100. The operations OP61-OP62 are performed in order. The schematic diagrams shown in FIG. 6A and FIG. 6B correspond to intermediate states of the semiconductor device 100 during a routing process of the method.

As illustrated in FIG. 6A, the semiconductor device 100 includes the G-cells 600. The G-cells 600 include at least G-cells G11, G21, G12 and G22. The G-cells 600 are arranged along a horizontal direction and a vertical direction and are adjacent to each other. At the operation OP61, a routing region of each layer is partitioned into multiple G-cells for any-angle routing. Specifically, each layer of the semiconductor device 100 is partitioned into the G-cells 600, and the G-cells 600 are implemented by variable polygon-styles and are placed evenly-distributed or irregularly. For example, the G-cells 600 are octagon G-cells.

In some embodiments, any-degree bundle global routes over G-cells are planned. Any-angle detail routes are guided within G-cells. For example, a bundle route BR1 is created crossing over G-cells G11 to G21 along an arrow AR1. A bundle route BR2 is created crossing over G-cells G11 to G12 along an arrow AR2. A bundle route BR3 is created crossing over G-cells G12 to G21 along an arrow AR4. A bundle route BR4 is created crossing over G-cells G11 to G22 along an arrow AR3. The arrow AR1 indicates a horizontal direction corresponding to 0 degree. The arrow AR2 indicates a vertical direction corresponding to 90 degrees. The arrow AR4 indicates a direction of an inclined 45 degrees clockwise to the horizontal direction corresponding to 135 degrees. The arrow AR3 indicates a direction of an inclined 45 degrees counterclockwise to the horizontal direction corresponding to 45 degrees.

As illustrated in FIG. 6B, the G-cells 600 further includes pins P1-P4, bundle routes BR61 and BR62, G-cells G23, G31, G41, G42 and G43. The pin P1 is located over G-cell G11. The pin P2 is located over G-cell G23. The pin P3 is located over G-cell G21. The pin P4 is located over G-cell G43. The bundle route BR61 connects the pins P1 and P2 and crosses over G-cells G11, G12 and G23. The bundle route BR62 connects the pins P3 and P4 and crosses over G-cells G21, G31, G41, G42 and G43. In some embodiments, pins P1-P4 correspond to bumps, balls or vias.

At the operation OP62, bundle routes are planned over G-cells. Specifically, the bundle route BR61 are created over the G-cells G11, G12 and G23, and the bundle route BR62 are created over the G-cells G21, G31, G41, G42 and G43.

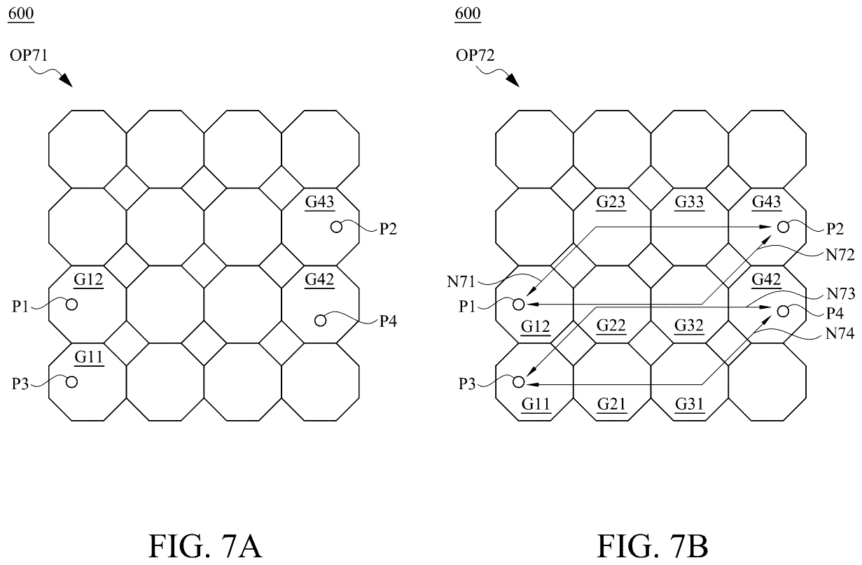

FIG. 7A and FIG. 7B are schematic diagrams of G-cells 600 in the semiconductor device 100 corresponding to a method including operations OP71 and OP72, in accordance with some embodiments of the present disclosure. In some embodiments, the method is performed by the EDA tool to route the semiconductor device 100. The operations OP71-OP72 are performed in order. The schematic diagrams shown in FIG. 7A and FIG. 7B correspond to intermediate states of the semiconductor device 100 during a routing process of the method.

As illustrated in FIG. 7A, the semiconductor device 100 includes the G-cells 600. The G-cells 600 include the pins P1-P4 and at least G-cells G11, G12, G42 and G43. The pin P1 is located over G-cell G12. The pin P2 is located over G-cell G43. The pin P3 is located over G-cell G11. The pin P4 is located over G-cell G42.

At the operation OP71, G-cell capacities are evaluated. Specifically, edge capacities of the G-cells 600 are calculated. In some embodiments, G-cell edges associate capacity and demand to model routing resource. For example, a G-cell edge capacity indicates a number of nets available to cross over the G-cell edge, and a demand indicates a number of nets demanded by a bundle route to cross over the G-cell edge. When a G-cell edge capacity is larger than or equal to a demand of a bundle route, the bundle route is allowed to be arranged over the G-cell edge. When a G-cell edge capacity is less than a demand of a bundle route, the bundle route is either not allowed to be arranged over the G-cell edge or an overflow violation occurs. Further details regarding edge capacities of the G-cells are discussed in FIG. 8A and FIG. 8B.

As illustrated in FIG. 7B, the G-cells 600 further include the nets N71-N74 and at least G-cells G21, G31, G22, G32, G23 and G33. The net N71 connects the pins P1 and P2 and crosses over G-cells G12, G23, G33 and G43. The net N72 connects the pins P1 and P2 and crosses over G-cells G12, G22, G32 and G43. The net N73 connects the pins P3 and P4 and crosses over G-cells G11, G22, G32 and G42. The net N74 connects the pins P3 and P4 and crosses over G-cells G11, G21, G31 and G42. In some embodiments, the nets N71 and N72 are possible routes corresponding to a bundle route connecting the pins P1 and P2, and the nets N73 and N74 are possible routes corresponding to a bundle route connecting the pins P3 and P4.

At the operation OP72, congestion optimized routes are created. Specifically, congestion indicates a degree of a number of nets occupying an edge of a G-cell. Route arrangements with a smaller number of nets occupying edges of a G-cell correspond to congestion optimized routes. For example, when the pins P1 and P2 are connected by the net N72 and the pins P3 and P4 are connected by the net N73, the edge shared by the G-cells G22 and G32 are occupied by a larger number of nets. Therefore, the route arrangements of the nets N72 and N73 are not recommended and are not created.

In contrast, when the pins P1 and P2 are connected by the net N72 and the pins P3 and P4 are connected by the net N74, the edge shared by the G-cells G22 and G32 are occupied by a smaller number of nets. Therefore, the route arrangements of the nets N72 and N74 are recommended and are created. Similarly, the route arrangements of the nets N71 and N73 and the route arrangements of the nets N71 and N74 are recommended and are created.

In some embodiments, congestion can be represented by route density on each G-cell edge or G-cell, such as an average route density of its G-cell edges. A route density is such as a demand and/or a capacity. The EDA tool can propose alternative models, such as bundle global routes, route density of G-cell edges and a congestion map.

FIG. 8A and FIG. 8B are schematic diagrams of a G-cell 800 in the semiconductor device 100 corresponding to a method including operations OP81 and OP82, in accordance with some embodiments of the present disclosure. In some embodiments, the method is performed by the EDA tool to route the semiconductor device 100. The operations OP81-OP82 are performed in order. The schematic diagrams shown in FIG. 8A and FIG. 8B correspond to intermediate states of the semiconductor device 100 during a routing process of the method.

As illustrated in FIG. 8A, the G-cell 800 includes edges E81-E83. The semiconductor device 100 includes nets N11-N16, N21-N26, N31, N32 and a blockage BL1. Each of the nets N11-N16 crosses over the edge E81. Each of the nets N21-N26 crosses over the edge E82. Each of the nets N31 and N32 crosses over the edge E83. The blockage BL1 overlaps the edge E83 at an edge portion PO1.

At the operation OP81, edge capacities are evaluated. Specifically, each edge of a G-cell has an edge capacity. An edge capacity of an edge of a G-cell represents a number of nets that can be arranged crossing over the edge of the G-cell without spacing violation and models available resources, such as a line/space (L/S) rule and blockages. An edge capacity of an edge of a G-cell is set and calculated by a non-blocked edge length divided by a trace pitch. A non-blocked edge length is a length of an edge of a G-cell minus a length of an edge of a G-cell overlapped by a blockage. A trace pitch is a sum of a width of a net and a space between adjacent nets.

For example, the edge E81 has a length of 24 micrometers (μm). Each of the nets N11-N16 has a width of 2 μm. Two adjacent nets are separated from each other by a distance of 2 μm. Specifically, the distance between the nets N11 and N12 is 2 μm, the distance between the nets N12 and N13 is 2 μm, the distance between the nets N13 and N14 is 2 μm, the distance between the nets N14 and N15 is 2 μm, and the distance between the nets N15 and N16 is 2 μm. Accordingly, the edge capacity of the edge E81 is 24/(2+2)=6. Alternatively stated, the edge E81 is available for 6 nets to cross over. Similarly, the edge E82 has a length of 24 μm, each of the nets N21-N26 has a width of 2 μm, and each of distances between adjacent nets of the nets N21-N26 has a space of 2 μm. Therefore, the edge capacity of the edge E82 is 24/(2+2)=6. Alternatively stated, the edge E82 is available for 6 nets to cross over.

On the other hand, the edge capacity is also associated with the blockage overlapped with the corresponding edge. For example, the edge E83 has a length of 24 μm. Each of the nets N31 and N32 has a width of 2 μm. The distance between the nets N31 and N32 is 2 μm. The blockage BL1 overlaps with the edge E83 to block the edge portion PO1 of the edge E83, in which a length of the edge portion PO1 is 16 μm. Alternatively stated, 16 μm of the edge E83 is blocked by the blockage BL1. Accordingly, the edge capacity of the edge E83 is (24−16)/(2+2)=2. Alternatively stated, the edge E83 is available for 2 nets to cross over.

In summary, when the length of the edge of the G-cell is increased, the corresponding edge capacity of the edge is increased. When the length of the edge portion blocked by a blockage is increased, the corresponding edge capacity of the edge is decreased. When the width of the net is increased, the corresponding edge capacity of the edge is decreased. When the space between adjacent nets is increased, the corresponding edge capacity of the edge is decreased. In some embodiments, the width of the net is equal to the width of the route.

In some embodiments, referring to FIG. 8A and FIG. 1D, FIG. 4E and FIG. 5C, the spaces between adjacent nets in FIG. 8A corresponds to the spaces in FIG. 1D, FIG. 4E and FIG. 5C. For example, the space between the nets N11 and N12 corresponds to the space SP1. The space between the nets N12 and N13 corresponds to the space SP2. The space between the nets N21 and N22 corresponds to the space SP3. The space between the nets N22 and N23 corresponds to the space SP4. The space between the nets N23 and N24 corresponds to the space SP5.

As illustrated in FIG. 8B, the semiconductor device 100 includes bundle routes BR81-BR84 instead of nets N11-N16, N21-N26, N31, N32 and the blockage BL1. The bundle route BR81 crosses over the edge E81. Each of the bundle routes BR82 and BR83 crosses over the edge E82. The bundle route BR84 crosses over the edge E83.

At the operation OP82, bundle routes over G-cells are arranged. Specifically, when a number of nets demanded by a bundle route is smaller or equal to an edge capacity of the corresponding edge of the G-cell, the bundle route is allowed to be arranged crossing over the corresponding edge. For example, in response to a number of nets demanded by the bundle route BR81 is 4 and an edge capacity of the edge E81 is 6, the bundle route BR81 is allowed to be arranged crossing over the edge E81. In some embodiments, a bundle route is generated according to a bundle and G-cells.

Also at the operation OP82, when a number of nets demanded by multiple bundle routes is smaller or equal to an edge capacity of the corresponding edge of the G-cell, the multiple bundle routes are allowed to be arranged crossing over the corresponding edge. For example, in response to a number of nets demanded by the bundle route BR82 is 2, a number of nets demanded by the bundle route BR83 is 4, and an edge capacity of the edge E81 is 6, the bundle routes BR82 and BR83 are allowed to be arranged crossing over the edge E82. In some embodiments, the bundle routes BR82 and BR83 are separated from each other.

Also at the operation OP82, when a number of nets demanded by one or more bundle route is larger than an edge capacity of the corresponding edge of the G-cell, the one or more bundle route is considered to be overflowed or is not allowed to be arranged crossing over the corresponding edge. For example, in response to a number of nets demanded by the bundle route BR84 is 3 and an edge capacity of the edge E83 is 2, the bundle route BR84 is not allowed to be arranged crossing over the edge E82 or overflow violations occur.

In some embodiments, when the bundle routes BR81-BR83 is allowed to be arranged crossing over the corresponding edges E81-E82 of the G-cell 800, routes are generated along the corresponding bundle routes BR81-BR83. Accordingly, 4 routes corresponding to the 4 nets in the bundle route BR81 are generated crossing over the edge E81 along the bundle route BR81. 2 routes corresponding to the 2 nets in the bundle route BR82 and 4 routes corresponding to the 4 nets in the bundle route BR83 are generated crossing over the edge E82 along the bundle routes BR82 and BR83, respectively. In contrast, when the bundle route BR84 is not allowed to be arranged crossing over the corresponding edge E83 of the G-cell 800, 3 routes corresponding to the 3 nets in the bundle route BR84 are either not generated over the edge E83 or generated with spacing violations, and are generated over an edge of the G-cell 800 having an edge capacity equal to or more than 3.

In some embodiments, the edge capacity setting in FIG. 8A and FIG. 8B serves for illustration purpose but does not intend to be implemented as is. Alternative models are applicable for implementation. For example, alternative models can lump capacity and/or demand of all layers into a single-layer G-cells and optimize bundle routes.

Referring to FIG. 1C and FIG. 8B, in some embodiments, the bundle route BR1 is implemented by one of the bundles BR81-BR83. Referring to FIG. 5C and FIG. 8B, in some embodiments, the bundle routes BR1-BR2 are implemented by the bundles BR82 and BR83, respectively.

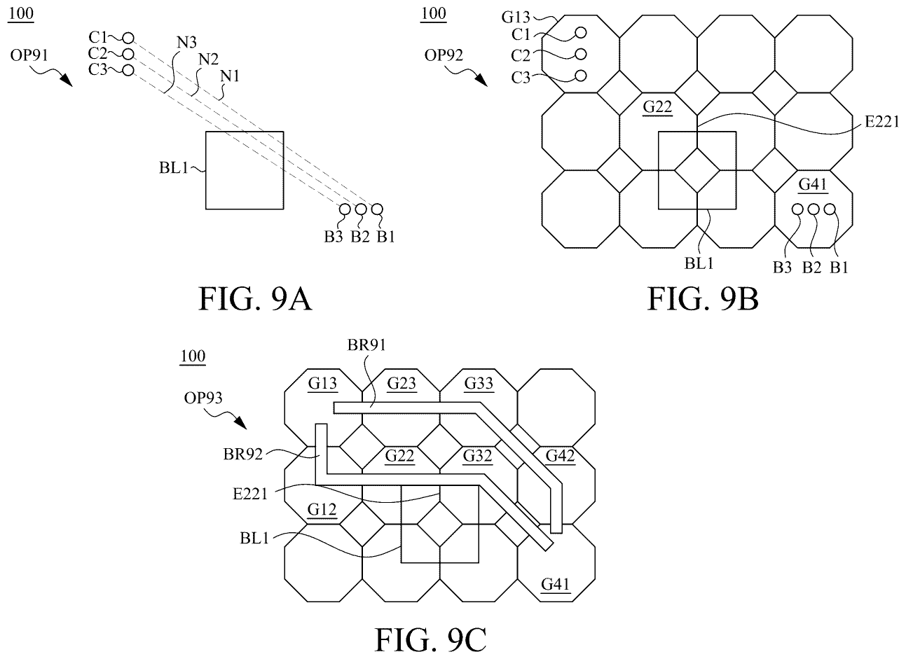

FIG. 9A to FIG. 9C are schematic diagrams of a semiconductor device 100 corresponding to a method including operations OP91-OP93, in accordance with some embodiments of the present disclosure. In some embodiments, the method is performed by the EDA tool to route the semiconductor device 100. The operations OP91-OP93 are performed in order. The schematic diagrams shown in FIG. 9A and FIG. 9C correspond to intermediate states of the semiconductor device 100 during a routing process of the method.

As illustrated in FIG. 9A, the semiconductor device 100 includes a blockage BL1, bumps C1-C3, balls B1-B3 and nets N1-N3. The blockage BL1 overlaps portions of the nets N1-N3. At the operation OP91, flylines are created. Specifically, the bump C1 is connected to the ball B1 through the net N1. The bump C2 is connected to the ball B2 through the net N2. The bump C3 is connected to the ball B3 through the net N3. In some embodiments, nets N1-N3 are flylines.

As illustrated in FIG. 9B, the semiconductor device 100 further includes the G-cells 600. The G-cells 600 include at least G-cells G13, G22 and G41. The bumps C1-C3 are located over the G-cell G13. The balls B1-B3 are located over the G-cell G41. Part of the blockage BL1 is located over the G-cell G22 and an edge E221 of the G-cell G22. At the operation OP92, G-cell edge capacities are evaluated. Specifically, the semiconductor device 100 is partitioned by G-cells 600 into multiple G-cells, and edge capacities of edges of the G-cells 600 are calculated by a number of bundle routes available to be arranged crossing over the edges of the G-cells according to locations of blockages.

For example, an edge capacity of each edge of the G-cell G13 is 6. An edge capacity of the edge E221 of the G-cell G22 is 2 according to a location of the blockage BL1. Alternatively stated, no blockages are over the G-cell G13. Accordingly, six bundle routes are allowed to be arranged over each edge of the G-cell G13. Part of the blockage BL1 is located over the edge E221 of the G-cell G22. Accordingly, two bundle routes are allowed to be arranged over the edge E221. In some embodiments, a bundle route corresponds to a net.

As illustrated in FIG. 9C, the G-cells 600 further include bundle routes BR91 and BR92, G-cells G23, G33, G12, G32 and G42. The bundle route BR91 connects bumps C1-C3 and balls B1-B3 and crosses over the G-cells G13, G23, G33, G42 and G41. The bundle route BR92 connects bumps C1-C3 and balls B1-B3 and crosses over the G-cells G13, G12, G22, G32 and G41. In some embodiments, each of the bundle routes BR91 and BR92 includes nets N1-N3. Accordingly, each of the demand of the bundle routes BR91 and BR92 is 3.

At the operation OP93, congestion-driven paths are searched by bundle global routes to satisfy edge capacities of G-cells. Specifically, a bundle route is created over G-cells with edge capacities larger than a demand of the bundle route. An overflow is a number of nets exceeding the edge capacity of an edge of a G-cell.

For example, the demand of the bundle route BR91 is 3, and each of the edges crossed over by the route BR91 has an edge capacity of 6, which is larger than the demand of the bundle route BR91. Accordingly, the bundle route BR91 is a better path with an overflow of 0. Alternatively stated, the bundle route BR91 is allowed to be arranged crossing over the corresponding edges.

In contrast, the demand of the bundle route BR92 is 3, and the edge E221 crossed over by the route BR92 has an edge capacity of 2, which is less than the demand of the bundle route BR92. Accordingly, the bundle route BR92 is a worse path with an overflow of 1. Alternatively stated, the bundle route BR92 is either not allowed or not desired to be arranged crossing over the edge E221.

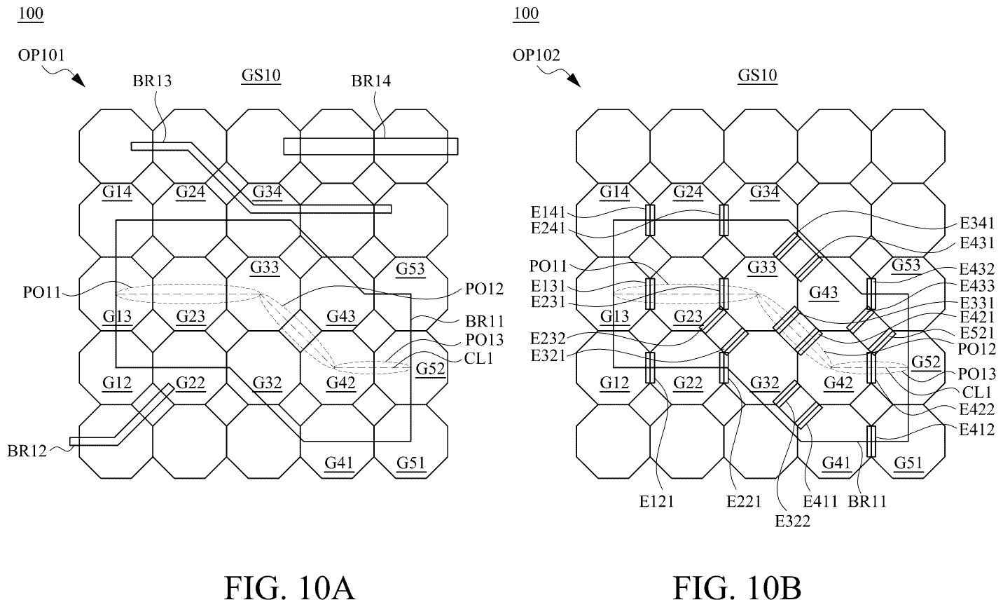

FIG. 10A to FIG. 10B are schematic diagrams of a semiconductor device 100 corresponding to a method including operations OP101-OP102, in accordance with some embodiments of the present disclosure. In some embodiments, the method is performed by the EDA tool to route the semiconductor device 100. The operations OP101-OP102 are performed in order. The schematic diagrams shown in FIG. 10A and FIG. 10B correspond to intermediate states of the semiconductor device 100 during a routing process of the method.

As illustrated in FIG. 10A and FIG. 10B, the semiconductor device 100 includes G-cells GS10 and bundle routes BR11-BR14. The bundle route BR11 includes 12 nets. The bundle route BR12 includes 2 nets. The bundle route BR13 includes 2 nets. The bundle route BR14 includes 4 nets.

In some embodiments, a fat bundle route is a bundle route including a number of nets which exceeds an edge capacity of an edge of a G-cell. For example, the edge capacity of one edge of one of the G-cells GS10 is 6, and the number of nets of the bundle route BR11 is 12, which is larger than 6. Accordingly, the bundle route BR11 is referred to as a fat bundle route.

At the operation OP101, a fat bundle route is arranged, and G-cell to G-cell paths for a center line of a fat bundle route is searched. Specifically, the bundle route BR11 is arranged on G-cells G12-G14, G22-G24, G32-G34, G41-G43, G51-G53 of the G-cells GS10, and a center line CL1 of the bundle route BR11 is searched on the G-cells G13, G23, G33, G42 and G52. In some embodiments, the center line CL1 is parallel to the bundle route BR11 and is located in the middle of the bundle route BR11.

As illustrated in FIG. 10A and FIG. 10B, the center line CL1 crosses over the edges of the G-cells G13, G23, G33, G42 and G52. The fat bundle route BR11 crosses over the edges of the G-cells G13, G23, G33, G42 and G52, and further crosses over the edges of the G-cells G12, G14, G22, G24, G32, G34, G41, G43, G51 and G53 adjacent to the G-cells G13, G23, G33, G42 and G52.

Specifically, the number of nets of the fat bundle route BR11 is 12, and a portion PO11 of the center line CL1 is arranged between the G-cells G13, G23 and G33 along a horizontal direction. Accordingly, three routes of the bundle route BR11 are generated crossing over each of the edges E141 and E241, other six routes of the bundle route BR11 are generated crossing over the edges E131 and E231, and the rest three routes of the bundle route BR11 are generated crossing over the edge E121 and E221. In some embodiments, each of the edges E141, E241, E131, E231, E121 and E221 extends along a vertical direction. The portion PO11 of the center line CL1 is perpendicular to each of the edges E141, E241, E131, E231, E121 and E221, and bisects the edges E131 and E231 into two equal parts.

A portion PO12 of the center line CL1 is arranged between the G-cells G33 and G42 along the direction of an inclined 45 degrees clockwise to the horizontal direction. Accordingly, the three routes of the bundle route BR11 are generated crossing over the edges E341, E431, E433, and E521, the six routes of the bundle route BR11 are generated crossing over the edges E331 and E421, and the rest three routes of the bundle route BR11 are generated crossing over the edges E322, E411, E232, and E321. In some embodiments, each of the edges E341, E431, E331, E421, E322 and E411 extends along the direction of an inclined 45 degrees clockwise to the vertical direction. The portion PO12 of the center line CL1 is perpendicular to each of the edges E341, E431, E331, E421, E322 and E411, and bisects the edges E331 and E421 into two equal parts.

A portion PO13 of the center line CL1 is arranged between the G-cells G42 and G52 along the horizontal direction. Accordingly, the three routes of the bundle route BR11 are generated crossing over the edge E432, the six routes of the bundle route BR11 are generated crossing over the edge E422, and the rest three routes of the bundle route BR11 are generated crossing over the edge E412. In some embodiments, each of the edges E432, E422 and E412 extends along the vertical direction. The portion PO13 of the center line CL1 is perpendicular to each of the edges E432, E422 and E412, and bisects the edges E422 into two equal parts.

As illustrated in FIG. 10B, the semiconductor device 100 includes the G-cells GS10 and the bundle route BR11. At the operation OP102, demands of adjacent G-cells are updated according to the G-cell to G-cell paths for a center line of a fat bundle route. Specifically, numbers of nets demanded by the fat bundle route on the edges of the adjacent G-cells are generated according to the center line of the fat bundle route.

For example, the number of nets demanded by the fat bundle route BR11 is 12. Accordingly, a demand of an edge E141 of the G-cell G14 is updated to 3, a demand of an edge E131 of the G-cell G13 is updated to 6, and a demand of an edge E121 of the G-cell G12 is updated to 3. A demand of an edge E241 of the G-cell G24 is updated to 3, a demand of an edge E231 of the G-cell G23 is updated to 3, a demand of an edge E232 of the G-cell G23 is updated to 3, a demand of an edge E221 of the G-cell G22 is updated to 3, and a demand of an edge E321 of a G-cell G32 is updated to 3. Demands of an edge E341 of the G-cell G34 and an edge E431 of the G-cell G43 are updated to 3, demands of an edge E331 of the G-cell G33 and an edge E421 of the G-cell G42 are updated to 6, and demands of an edge E322 of the G-cell G32 and an edge E411 of the G-cell G41 are updated to 3. Demands of an edge E412 of the G-cell G41, an edge E433 of the G-cell G43, and an edge E521 of the G-cell G52 are updated to 3. A demand of an edge E422 of the G-cell G42 are updated to 6.

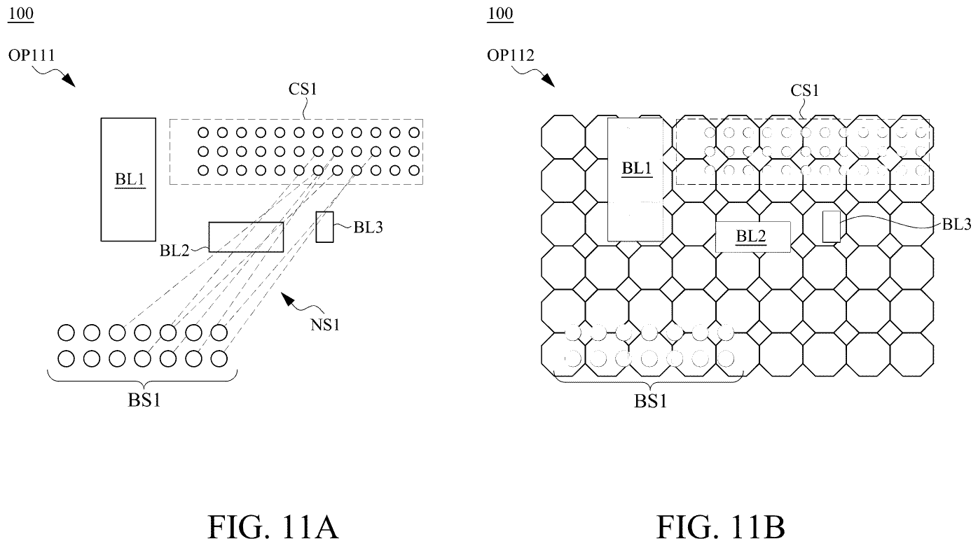

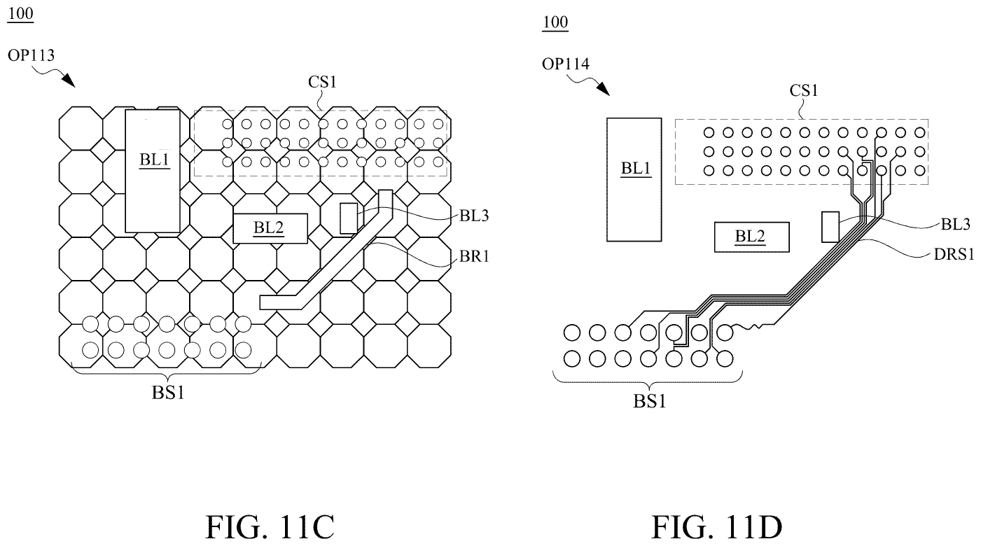

FIG. 11A to FIG. 11D are schematic diagrams of the semiconductor device 100 corresponding to a method including operations OP111-OP114, in accordance with some embodiments of the present disclosure. In some embodiments, the method is performed by the EDA tool to route the semiconductor device 100. The operations OP111-OP114 are performed in order. The schematic diagrams shown in FIG. 11A to FIG. 11D correspond to intermediate states of the semiconductor device 100 during a routing process of the method.

As illustrated in FIG. 11A, the semiconductor device 100 includes bumps CS1, balls BS1, nets NS1 and blockages BL1-BL3. The bumps CS1 and the balls BS1 are connected by the nets NS1. Part of the nets NS1 cross over the blockages BL2 and BL3. In some embodiments, the bumps CS1 are included in the circuit CI1. At the operation OP111, a route region and flylines are created. Specifically, the route region corresponds to the semiconductor device 100. The nets NS1 correspond to the flylines.

As illustrated in FIG. 11B, the semiconductor device 100 further includes G-cells, such as G-cells 600 in FIG. 6A. The bumps CS1, the balls BS1, the nets NS1 and the blockages BL1-BL3 are over the G-cells. At the operation OP112, abstract graph for bundle global route and planning is created. Specifically, the G-cells are created and crossed over by the bumps CS1, the balls BS1, the nets NS1 and the blockages BL1-BL3.

As illustrated in FIG. 11C, the semiconductor device 100 further includes the bundle route BR1. The bumps CS1 and the balls BS1 are connected through the nets NS1 and the bundle route BR1. Compared to the nets NS1 in FIG. 11A, the bundle route BR1 bypasses the blockages BL2 and BL3. At the operation OP113, a bundle route over G-cells is created. Specifically, the bundle route BR1 is created according to edge capacities of edges of the G-cells and the blockages BL1-BL3. Each of the edges crossed over by the bundle route BR1 has an edge capacity more than a number of nets demanded by the bundle route BR1.

As illustrated in FIG. 11D, the semiconductor device 100 further includes routes DRS1 instead of the bundle route BR1. The bumps CS1 and the balls BS1 are electrically connected by the routes DRS1. At the operation OP114, detail routes are created. Specifically, the routes DRS1 are created along a direction parallel to the bundle route BR1 and the nets NS1. In some embodiments, each of the routes DRS1 is separated from each other.

In some embodiments, through the operations OP111-OP114, a bundle global route searches G-cell to G-cell global routing path for each bundle on the abstract path. The bundle routes are automatically created to save manual routing efforts. Congestions of all bundle routes for route planning on each layer are optimized. Regarding bundle routes for large substrate design, designers can plan non-overlapped bundle routes to guide mass of connections between pins, and route planning is efficient for complex designs, such as multi-routing layers, complex constraints and the like.

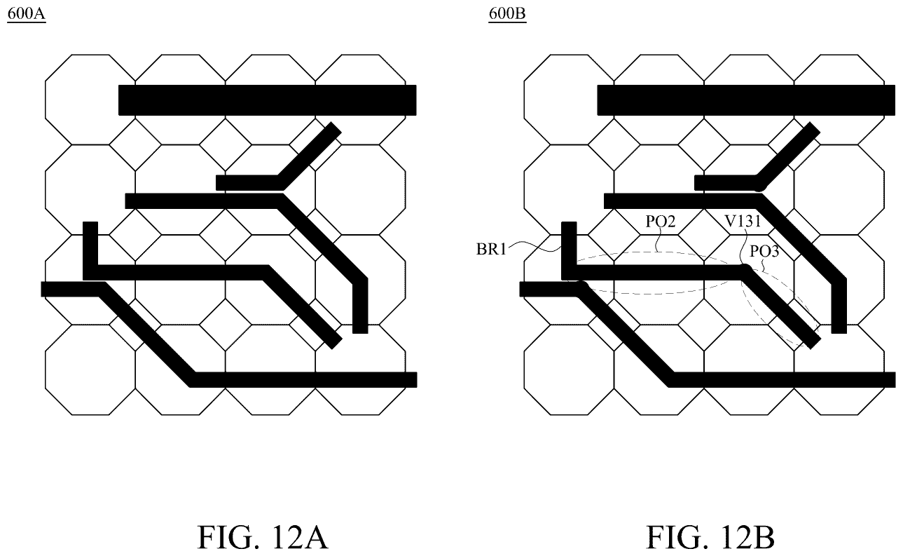

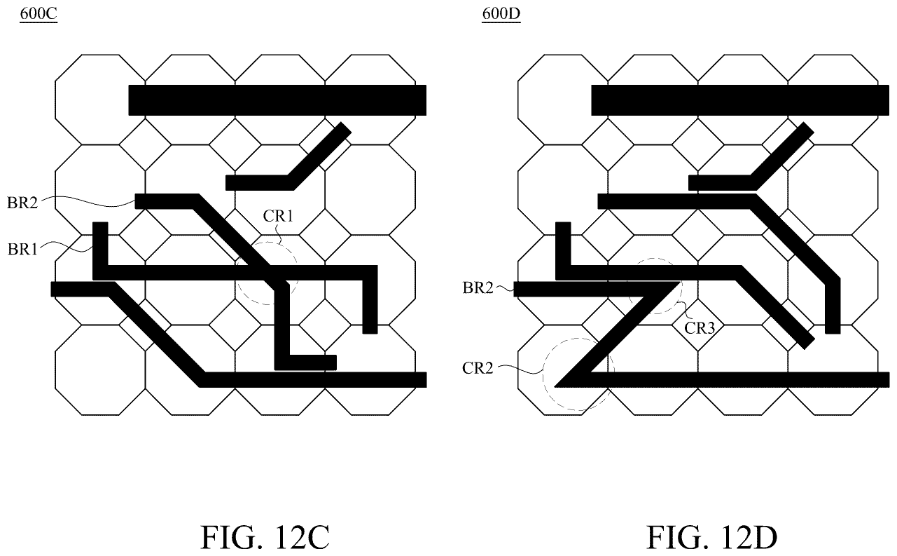

FIG. 12A to FIG. 12D are schematic diagrams of the G-cells 600A-600D in the semiconductor device 100 corresponding to a method, in accordance with some embodiments of the present disclosure. In some embodiments, the method is performed by the EDA tool to route the semiconductor device 100. The schematic diagrams shown in FIG. 12A to FIG. 12D correspond to intermediate states of the semiconductor device 100 during a routing process of the method. In some embodiments, each of the G-cells 600A-600D correspond to the G-cells 600.

As illustrated in FIG. 12A, the semiconductor device 100 includes multiple bundle routes over G-cells 600A. In some embodiments, the bundle routes in FIG. 12A are feasible and are created to generate routes.

As illustrated in FIG. 12B, the semiconductor device 100 includes multiple bundle routes including the bundle route BR1 over the G-cells 600B. A portion PO2 of the bundle route BR1 is on a layer L2, a portion PO3 of the bundle route BR1 is on a layer L3, and the portions PO2 and PO3 are connected through a via V131. In some embodiments, the bundle route BR1 in FIG. 12B is referred to as a cross-layer bundle route and is not preferred. Specifically, bundle routes are preferred to route on the same layer to reduce via impedance impact, and layer transition should be employed only to resolve significant congestion.

As illustrated in FIG. 12C, the semiconductor device 100 includes multiple bundle routes including the bundle routes BR1 and BR2 over the G-cells 600C. The bundle routes BR1 and BR2 are on the same layer and are overlapped with each other in a region CR1. In some embodiments, each of the bundle routes BR1 and BR2 in FIG. 12C is referred to as a bundle route crossover and is not allowed to be created to generate routes. Specifically, bundle routes do not overlap to each other on each layer.

As illustrated in FIG. 12D, the semiconductor device 100 includes multiple bundle routes including the bundle route BR2 over the G-cells 600C. The bundle route BR2 has an acute turning angle less than 90 degrees in a region CR2 and has an acute turning angle less than 90 degrees in a region CR3. In some embodiments, the bundle route BR2 in FIG. 12D is referred to as an acute turning angle route and is not allowed to be created to generate routes. Specifically, the allowed turning angle of a bundle route is obtuse or right, which is larger than or equal to 90 degrees.

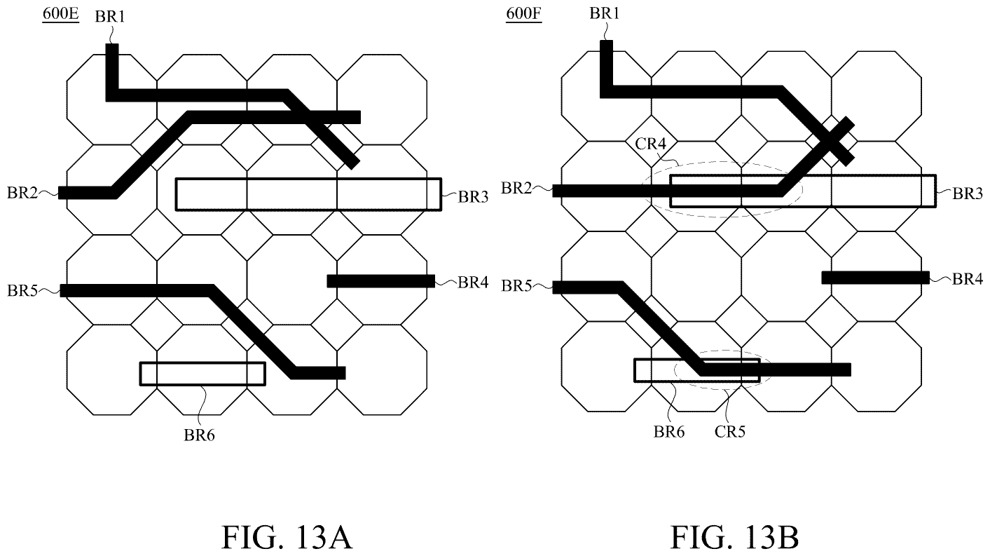

FIG. 13A and FIG. 13B are schematic diagrams of the G-cells 600E and 600F in the semiconductor device 100 corresponding to a method, in accordance with some embodiments of the present disclosure. In some embodiments, the method is performed by the EDA tool to route the semiconductor device 100. The schematic diagrams shown in FIG. 13A and FIG. 13B correspond to intermediate states of the semiconductor device 100 during a routing process of the method. In some embodiments, each of the G-cells 600A-600D correspond to the G-cells 600. Referring to FIG. 12A to FIG. 12D, FIG. 13A and FIG. 13B, in some embodiments, G-cells 600A-600F correspond to requirements for bundle route paths.

As illustrated in FIG. 13A, the semiconductor device 100 includes bundle routes BR1-BR6 over G-cells 600E. Each of the bundle routes BR1, BR3 and BR6 is on the layer L2, and each of the bundle routes BR2, BR4 and BR5 is on the layer L3. A portion of the bundle route BR1 overlaps a portion of the bundle route BR2. Each of the bundle routes BR3 and BR6 is a critical bundle route. Each of the bundle routes BR1, BR2, BR4 and BR5 is a non-critical bundle route.

In some embodiments, designs with limited layers may not have ground shielding planes adjacent to signal routing layers, and a critical bundle route is a bundle route with high speed and/or sensitivity. Accordingly, critical bundle routes are required not to be overlapped with signal routes in adjacent layers, such as non-critical bundle routes. Compared to non-critical bundle routes, critical bundle routes have higher weight and/or priority and are routed first to prevent non-critical bundle routes in adjacent layers.

As illustrated in FIG. 13A, adjacent-layer bundle routes are not overlapped with critical bundle routes. Specifically, bundle routes BR2 and BR5 are not overlapped with critical bundle routes BR3 and BR6, respectively. Accordingly, the bundle routes BR1-BR6 in FIG. 13A are feasible and are created to generate routes.

As illustrated in FIG. 13B, the semiconductor device 100 includes the bundle routes BR1-BR6 over G-cells 600F. Each of the bundle routes BR1, BR3 and BR6 is on the layer L2, and each of the bundle routes BR2, BR4 and BR5 is on the layer L3. A portion of the bundle route BR1 overlaps a portion of the bundle route BR2. The bundle routes BR2 and BR3 are on the adjacent layers and are overlapped with each other in a region CR4. The bundle routes BR5 and BR6 are on the adjacent layers and are overlapped with each other in a region CR5. Each of the bundle routes BR3 and BR6 is a critical bundle route. Each of the bundle routes BR1, BR2, BR4 and BR5 is a non-critical bundle route.

As illustrated in FIG. 13B, critical bundle routes are overlapped with adjacent-layer bundle routes. Specifically, bundle routes BR2 and BR5 are overlapped with critical bundle routes BR3 and BR6, respectively. Accordingly, the bundle routes BR1-BR6 in FIG. 13B are not allowed and are not created to generate routes.

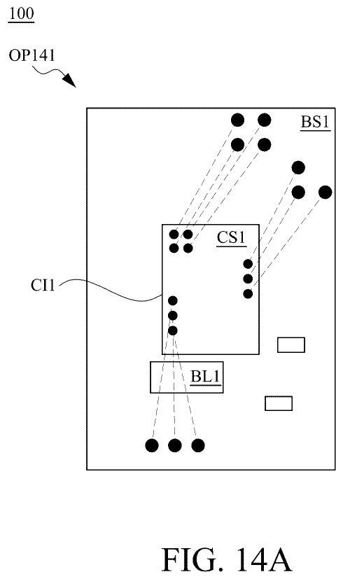

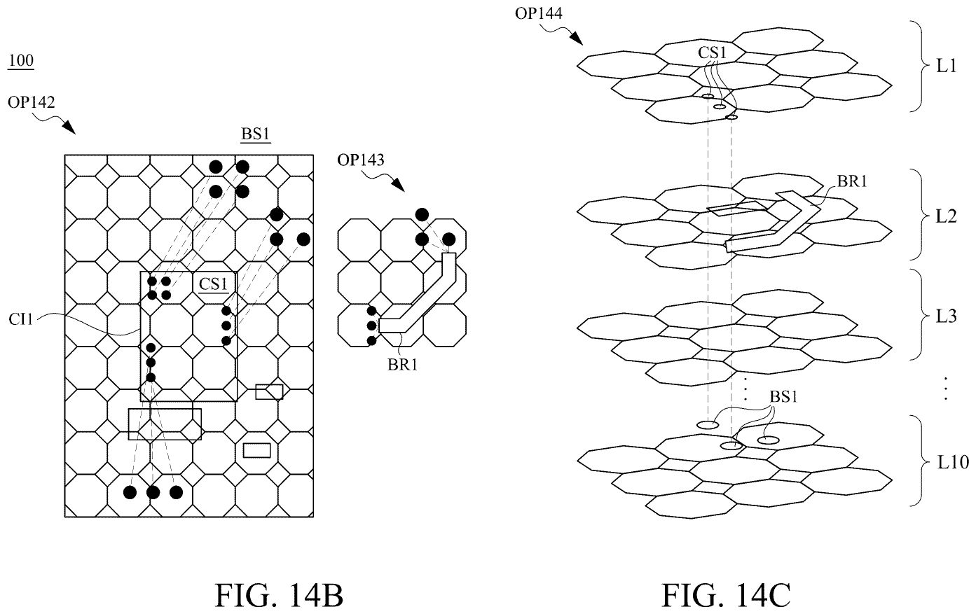

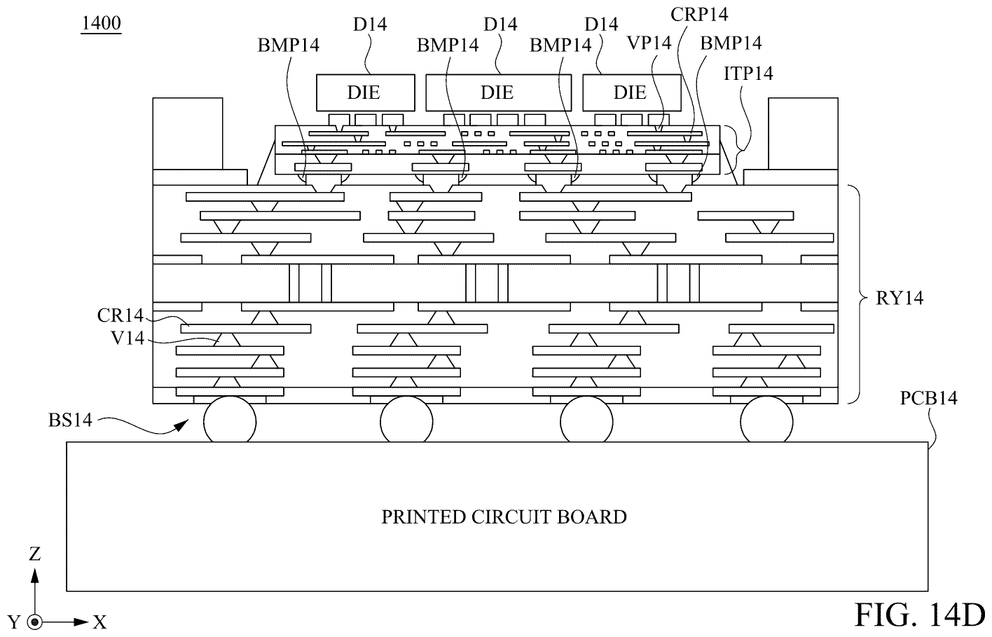

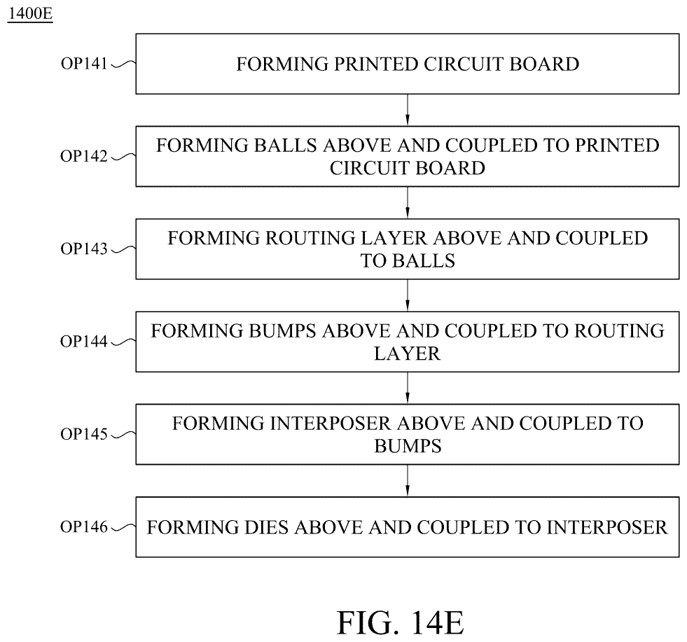

FIG. 14A to FIG. 14C are schematic diagrams of a semiconductor device 100 corresponding to a method including operations OP141-OP144, in accordance with some embodiments of the present disclosure. In some embodiments, the method is performed by the electronic design automation (EDA) tool to route the semiconductor device 100. The operations OP141-OP144 are performed in order. The schematic diagrams shown in FIG. 14A to FIG. 14C correspond to intermediate states of the semiconductor device 100 during a routing process of the method.

As illustrated in FIG. 14A, the semiconductor device 100 includes the circuit CI1, the balls BS1, nets and blockages. The circuit CI1 includes the bumps CS1. The blockages include a blockage BL1. The nets correspond to the nets NS1 in FIG. 11A. At the operation OP141, bumps and balls are connected through nets on a substrate. Specifically, the bumps CS1 are connected to the balls BS1 through the nets on a substrate of the semiconductor device 100.

As illustrated in FIG. 14B, the circuit CI1, the balls BS1, the nets and the blockages are arranged over G-cells, such as G-cells 600 in FIG. 6A. At the operation OP142, G-cells are created on a substrate. Specifically, G-cells are created to be arranged over by the circuit CI1, the balls BS1, the nets and the blockages on the substrate of the semiconductor device 100.

As illustrated in FIG. 14B, part of the bumps CS1 and part of the balls BS1 are connected by the bundle route BR1. At the operation OP143, bundle global routes are created. Specifically, bundle routes connecting the bumps CS1 and the balls BS1 are created according to the G-cells.

As illustrated in FIG. 14C, the bumps CS1 are located on the layer L1. The bundle route BR1 and one of the blockages are located on the layer L2. The balls BS1 are located on the layer L10. At the operation OP144, layers of a substrate are created, and bundle global routes are located on the layers. Specifically, layers L1-L10 are created, the bumps CS1 are located on the layer L1. The bundle route BR1 and one of the blockages are located on the layer L2. The balls BS1 are located on the layer L10. In some embodiments, each layer has its own G-cells and different capacities, such as edge capacities. Same G-cell size can be assumed among layers for global L/S rule.

Referring to FIG. 14A to FIG. 14C, in some embodiments, FIG. 14A and FIG. 14B are top views of the semiconductor device 100, and FIG. 14C is a layer view of the semiconductor device 100.

FIG. 14D is a cross sectional diagram of a structure 1400 corresponding to the route structures described above, in accordance with some embodiments of the present disclosure. As illustrated in FIG. 14D, the structure 1400 includes a printed circuit board PCB14, multiple balls BS14, a routing layer RY14, multiple bumps BMP14, an interposer ITP14 and multiple dies D14.

In some embodiments, the routing layer RY14 is implemented by a semiconductor bonding technology (SBT) substrate. The interposer ITP14 is implemented by a redistribution layer (RDL) interposer. The balls BS14 are implemented by a ball grid array (BGA). The bumps BMP14 are implemented by controlled collapsed of chip connection (C4) bumps. The dies D14 are implemented by active devices

As illustrated in FIG. 14D, along a Z direction, the balls BS14 are disposed above the printed circuit board PCB14, the routing layer RY14 is disposed above the balls BS14, the bumps BMP14 are disposed above the routing layer RY14, the interposer ITP14 is disposed above the bumps BMP14 and the dies D14 are disposed above the interposer ITP14.

In some embodiments, the routing layer RY14 includes multiple vias V14 and multiple conductive routes CR14. The vias V14 and the conductive routes CR14 are configured to couple the balls BS14 to the bumps BMP14. The interposer ITP14 includes multiple vias VP14 and multiple conductive routes CRP14. The vias VP14 and the conductive routes CRP14 are configured to couple the bumps BMP14 to the dies D14. In some embodiments, the vias V14, VP14 and the conductive routes CR14, CRP14 are implemented by conductive materials, such as metal.

In the embodiment shown in FIG. 14D, the balls BS14, the bumps BMP14 and the conductive routes CR14, CRP14 are arranged along an X-Y plane. The X-Y plane corresponds to an X direction and a Y direction. The Y direction points out from the paper. The X direction, the Y direction and the Z direction are perpendicular with each other.

Referring to FIG. 1A to FIG. 14D, the balls B1-B7 and BS1 are embodiments of the balls BS14, the bumps C1-C7 are embodiments of the bumps BMP14, the vias V11, V12, V21, V22, V31, V32, V42, V52, V62, V72 and V131 are embodiments of the vias V14, the routes DR1-DR7 and DRS1 are embodiments of the conductive routes CR14. The horizontal direction and the vertical direction shown in FIG. 1A to FIG. 14B correspond to the X direction and Y direction shown in FIG. 14D.

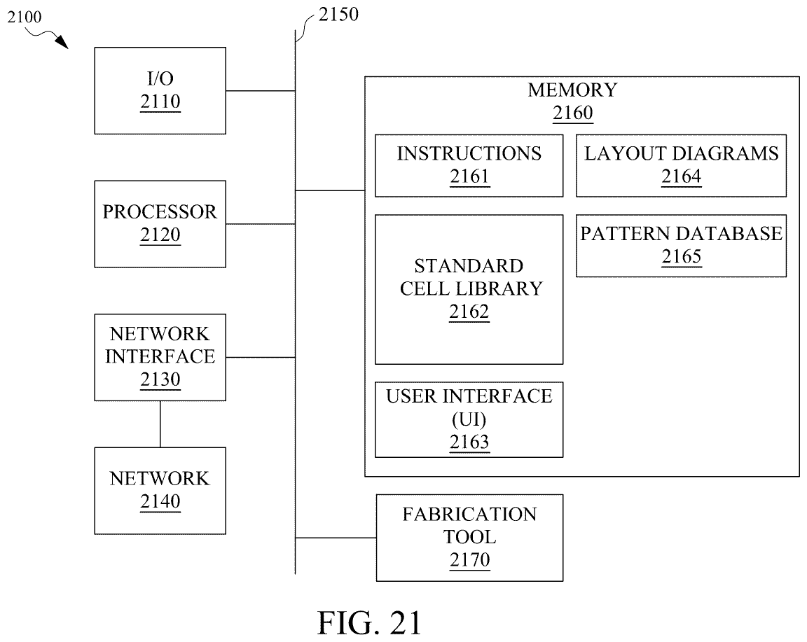

FIG. 14E is a flowchart diagram of a method 1400E for fabricating the structure 1400 shown in FIG. 14D, in accordance with some embodiments of the present disclosure. As illustrated in FIG. 14D, the method 1400E includes operations OP141-OP146. Referring to FIG. 14D and FIG. 21, the method 1400E is performed by the fabrication tool 2170 in some embodiments.

During the operation OP141, the printed circuit board PCB14 is formed.

During the operation OP142, the balls BS14 are formed above and coupled to the printed circuit board PCB14.

During the operation OP143, the routing layer RY14 is formed above and coupled to the balls BS14. Especially, the vias V14 and the conductive routes CR14 are formed to be coupled to the corresponding balls BS14. For example, referring to FIG. 5D and FIG. 14E, during the operation OP143, the routes DR1-DR7 are formed.

During the operation OP144, the bumps BMP14 are formed above and coupled to the routing layer RY14. Especially, the bumps BMP14 are formed to be coupled to the corresponding vias V14.

During the operation OP145, the interposer ITP14 is formed above and coupled to the bumps BMP14. Especially, the vias VP14 and the conductive routes CRP14 are formed to be coupled to the corresponding bumps BMP14.

During the operation OP146, the dies D14 are formed above and coupled to interposer ITP14. Especially, the dies D14 are formed to be coupled to the corresponding vias VP14.

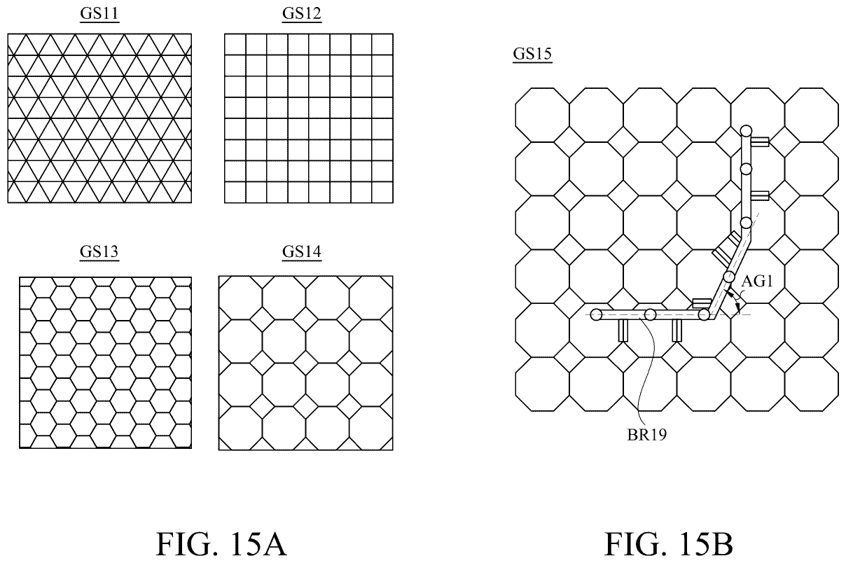

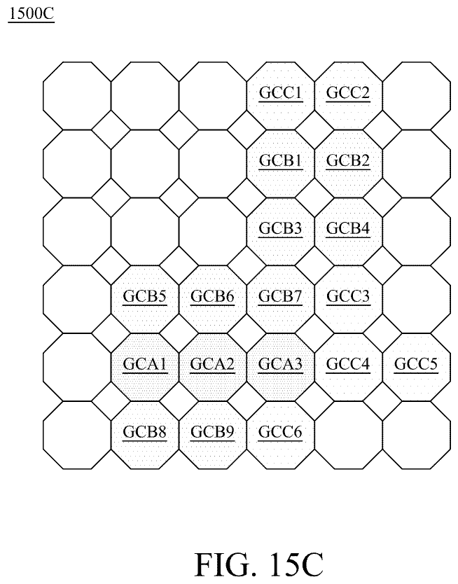

FIG. 15A and FIG. 15B are schematic diagrams of the G-cells GS11-GS15 in the semiconductor device 100 corresponding to a method, in accordance with some embodiments of the present disclosure. In some embodiments, the method is performed by the EDA tool to route the semiconductor device 100. The schematic diagrams shown in FIG. 15A to FIG. 15B correspond to intermediate states of the semiconductor device 100 during a routing process of the method. In some embodiments, each of the G-cells GS11-GS15 correspond to the G-cells 600.

As illustrated in FIG. 15A, a shape of each G-cell of the G-cells GS11 is a triangle with each angle of 60 degrees. A shape of each G-cell of the G-cells GS12 is a square with each angle of 90 degrees. A shape of each G-cell of the G-cells GS13 is a hexagon with each angle of 120 degrees. A shape of each G-cell of the G-cells GS14 is an octagon with each angle of 135 degrees. In some embodiments, G-cells GS11 are referred to as triangle G-cells. G-cells GS12 are referred to as square G-cells. G-cells GS13 are referred to as hexagon G-cells. G-cells GS14 are referred to as octagon G-cells.

In some embodiments, polygon-style G-cells are flexible for multi-angle routing. For example, bundle routes are allowed to be created at 30 degrees, 90 degrees and 120 degrees over the G-cells GS11. Bundle routes are allowed to be created at 0 degrees and 90 degrees over the G-cells GS12. Bundle routes are allowed to be created at 30 degrees, 90 degrees and 120 degrees over the G-cells GS13. Bundle routes are allowed to be created at 0 degrees, 45 degrees, 90 degrees and 135 degrees over the G-cells GS14.

In some embodiments, simplified and regular G-cells for global-route resource planning are used. Octagon G-cells let designers plan bundle global routes by more flexible 0/45/90/135-degree angle for route planning. The preferred direction constraint corresponds to better planar routability, such as the EDA tool default setting.

In some embodiments, spaces among G-cells can be also treated as a mixed placement of G-cells. For example, spaces among dodecagon G-cells are triangles. Accordingly, triangle G-cells are created as a mixed placement of dodecagon G-cells.

As illustrated in FIG. 15B, a shape of each G-cell of the G-cells GS15 is an octagon with each angle of 135 degrees. A bundle route BR19 is over the G-cells GS15 and has a turning angle AG1. In some embodiments, the angle AG1 is 70 degrees.

In some embodiments, detail routes can be realized by any-angle within G-cell paths, such as 70 degrees. G-cells with shapes of other kinds of polygons for other-angle routing can be used, such as dodecagon G-cells. In some embodiments, existed detail routes with arbitrary angles are imposed to demands of G-cell edges.

FIG. 15C are schematic diagrams of a congestion map 1500C, in accordance with some embodiments of the present disclosure. In some embodiments, the congestion map 1500C includes multiple G-cells with multiple congestion levels. The congestion levels indicate that a quantity of nets crossing over edges of a G-cell. When the quantity of the nets crossing over the edges of the G-cell is increased, the corresponding congestion level of the G-cell is increased. When the quantity of the nets crossing over the edges of the G-cell is decreased, the corresponding congestion level of the G-cell is decreased.

In the embodiment shown in FIG. 15C, the congestion map 1500C includes G-cells GCA1-GCA3, GCB1-GCB9 and GCC1-GCC6. Each of the G-cells GCA1-GCA3 has a first congestion level. Each of the G-cells GCB1-GCB9 has a second congestion level. Each of the G-cells GCC1-GCC6 has a third congestion level. Each of the G-cells other than the G-cells GCA1-GCA3, GCB1-GCB9 and GCC1-GCC6 has a fourth congestion level. In which the first congestion level is higher than the second congestion level, the second congestion level is higher than the third congestion level, and the third congestion level is higher than the fourth congestion level.

In some embodiments, the congestion map 1500C is configured to show and assess a route feasibility. Specifically, when the congestion levels of the congestion map 1500C is increased, the route feasibility is decreased. When the congestion levels of the congestion map 1500C is decreased, the route feasibility is increased.

In the embodiment shown in FIG. 15C, the G-cells of the congestion map 1500C are octagon shaped for 0-degree, 45-degree, 90-degree and 135-degree angle route planning. However, the embodiments of the present disclosure are not limited to this. Referring to FIG. 15A and FIG. 15C, in various embodiments, the G-cells of the congestion map 1500C have flexible polygon-style, such as triangles, squares or hexagons.

In various embodiments, the G-cells of the congestion map 1500C have a multi-layers structure. For example, referring to FIG. 14C and FIG. 15C, the congestion map 1500C includes G-cells of layers L1-L10 in some embodiments.

In some embodiments, when a route demand is larger than or equal to a global cell edge capacity, an overflow information is shown in the congestion map 1500C. For example, referring to FIG. 8A and FIG. 15C, the G-cell GCA1 is implemented by the G-cell 800. In such example, a global cell edge capacity of the edge E83 of the G-cell GCA1 is 2. When a route demand of the edge E83 is larger than or equal to 2, an overflow information is shown at the edge E83 of the congestion map 1500C.

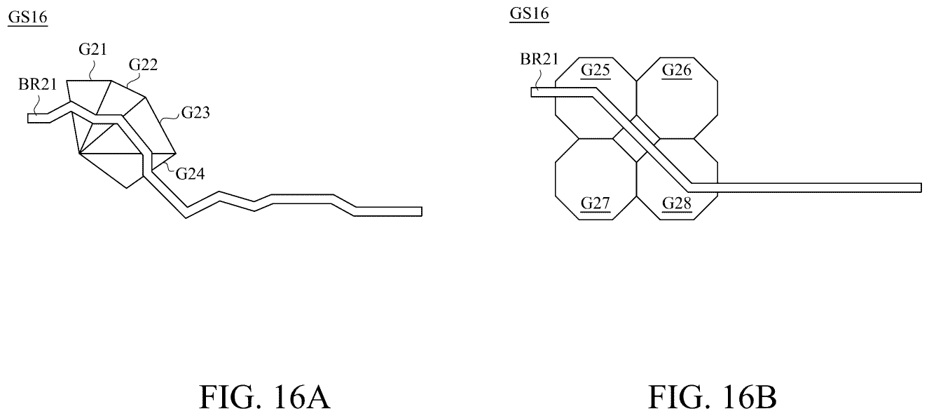

FIG. 16A and FIG. 16B are schematic diagrams of the G-cells GS16 in the semiconductor device 100 corresponding to a method, in accordance with some embodiments of the present disclosure. In some embodiments, the method is performed by the EDA tool to route the semiconductor device 100. The schematic diagrams shown in FIG. 16A to FIG. 16B correspond to intermediate states of the semiconductor device 100 during a routing process of the method. In some embodiments, the G-cells GS16 correspond to the G-cells 600.

As illustrated in FIG. 16A, the G-cells GS16 include G-cells G21-G24. Each of the G-cells G21-G24 is an irregular triangle different from each other. A bundle route BR21 crosses over the G-cells G21-G24.

As illustrated in FIG. 16B, the G-cells GS16 include G-cells G25-G28. Each of the G-cells G25-G28 is a regular octagon. A bundle route BR22 crosses over the G-cells G25 and G28.

In some embodiments, irregular G-cells are hard to plan resource, has a non-intuitive congestion map, and has many jogs in bundle and detail routes. Accordingly, irregular G-cells are acceptable but not recommended. Compared to FIG. 16A and FIG. 16B, the G-cells G21-G24 in FIG. 16A are irregular G-cells and the G-cells G25-G28 in FIG. 16B are regular G-cells. Accordingly, the jogs the bundle route BR21 has in FIG. 16A are more than the jogs the bundle route BR21 has in FIG. 16B.

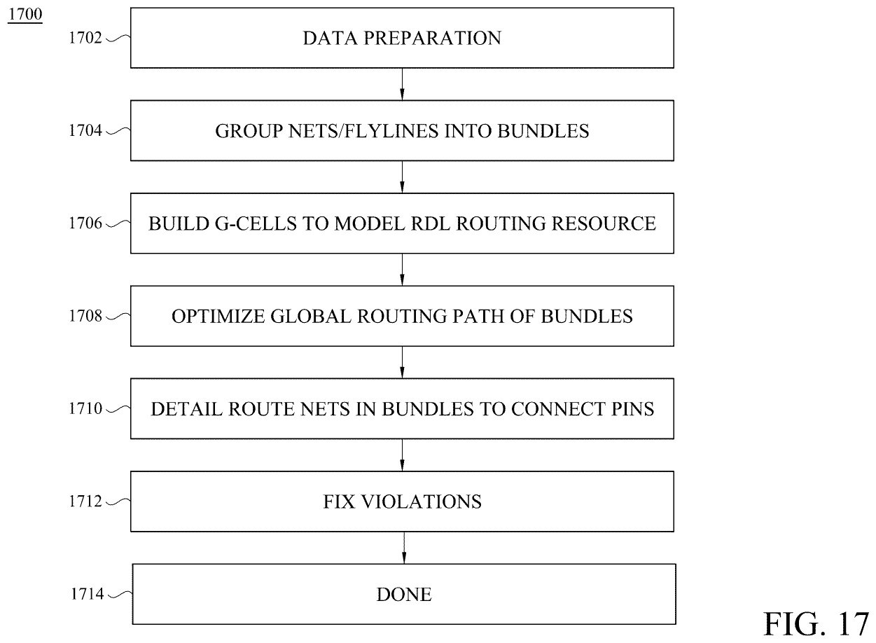

FIG. 17 is a flowchart of a method 1700 of routing a semiconductor device 100 in accordance with some embodiments of the present disclosure. As illustratively shown in FIG. 17, the method 1700 includes operations 1702, 1704, 1706, 1708, 1710, 1712 and 1714. In some embodiments, the method 1700 is performed to route the semiconductor device 100 described above.

At the operation 1702, data is prepared. Specifically, data associated with routing a semiconductor device is prepared, such as die/package sizes, bumps, balls, components, netlists, layers and blockages. For example, data such as the circuit CI1, the bumps C1-C7, the balls B1-B7, and the nets N1-N7 associated with routing the semiconductor device 100 is prepared. In some embodiments, the operation 1702 corresponds to each of the operations OP11, OP21, OP41, OP51 and OP52 described above.

At the operation 1704, nets and/or flylines are grouped into bundles. Specifically, nets and/or flylines are automatically grouped into bundles by functions, buses, groups, pin proximity, interactive setup or the like. For example, nets N1-N3 and N4-N7 are grouped into bundles BD1 and BD2, respectively. In some embodiments, the operation 1704 corresponds to each of the operations OP12, OP23, OP42 and OP53 described above.

At the operation 1706, G-cells are built to model routing resources of a redistribution layer (RDL). Specifically, G-cells are used and associated with capacity and demand. For example, G-cells 600 are created and associated with edge capacities and demands. In some embodiments, the operation 1706 corresponds to each of the operations OP61, OP71, OP92, OP112 and OP142 described above. In some embodiments, octagon G-cells are recommended. In other embodiments, polygons other than octagon are used as G-cells, such as dodecagon G-cells. In other embodiments, mixed irregular G-cells are used.

At the operation 1708, global routing paths of bundles are optimized. Specifically, global routing paths of bundles are optimized through iteratively optimizing congestions, showing congestion maps and global routing reports, such as overflow or violations, wire lengths (WL), number of vias and the like. For example, bundle routes BR1-BR6, BR61-BR62, BR81-BR83, BR91 and BR11 described above are optimized. In some embodiments, the operation 1708 corresponds to each of the operations OP13, OP43, OP44, OP54, OP62, OP72, OP82, OP93, OP101-OP102, OP113 and OP143-OP144 described above.

At the operation 1710, nets in bundles are routed to connect pins. Specifically, detail routing reports are generated, such as violations, WL, number of vias. For example, nets N1-N7 are routed to generate routes DR1-DR7 to connect bumps C1-C7 and balls B1-B7. In some embodiments, the operation 1710 corresponds to each of the operations OP14, OP45, OP54, OP81, OP114. In other embodiments, the operation 1710 is optional.

At the operation 1712, violations are fixed. Specifically, physical and electrical violations are fixed, such as spacing violations, skew matching violations and the like. In some embodiments, the operation 1712 is optional.

At the operation 1714, the routing process is done. Specifically, databases (DB) are outputted.

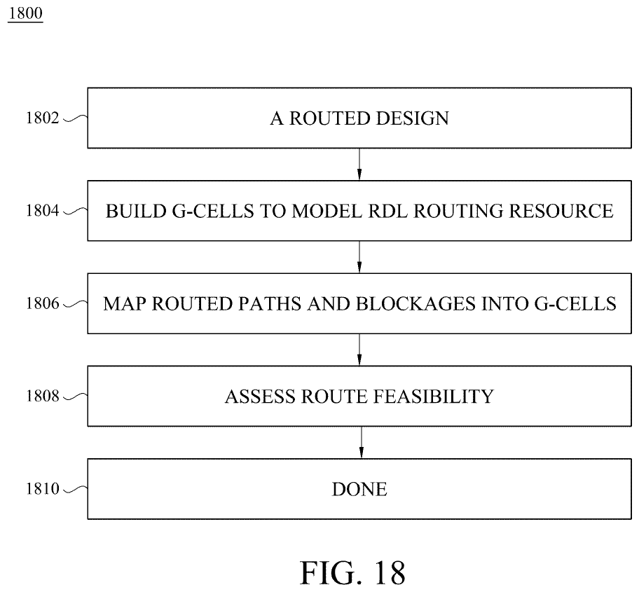

FIG. 18 is a flowchart of a method 1800 of routing a semiconductor device 100 in accordance with some embodiments of the present disclosure. As illustratively shown in FIG. 18, the method 1800 includes operations 1802, 1804, 1806, 1808, and 1810. In some embodiments, the method 1800 is performed to route the semiconductor device 100 described above.

At the operation 1802, a routed design is prepared. Specifically, a routed design includes data such as die/package sizes, bumps, balls, components, netlists, layers, blockages, full or partial sets of routed patterns. For example, a routed design including data such as the circuit CI1, the bumps C1-C7, the balls B1-B7, the nets N1-N7, layers L1-L10, blockages BL1-BL3 associated with routing the semiconductor device 100 is prepared. In some embodiments, the operation 1802 corresponds to each of the operations OP14, OP45, OP54 and OP114 described above.

The operation 1804 of the method 1800 is similar to the operation 1706 of the method 1700. Therefore, descriptions of the operation 1804 are omitted for brevity.

At the operation 1806, routed paths and blockages are mapped into G-cells. Specifically, G-cells are associated with capacity and demand.

At the operation 1808, route feasibility is assessed. Specifically, route feasibility is assessed through showing congestion maps and routing reports, such as overflow or violations, critical regions, WLs, number of vias and the like. In some embodiments, the operation 1808 corresponds to each of the operations OP72, OP81-OP82, OP93, OP101-OP102 and OP113. For example, nets N71-N74 of the operation OP72 are assessed. For another example, the route feasibility of the G-cells 600A-600F is assessed.

The operation 1810 of the method 1800 is similar to the operation 1714 of the method 1700. Therefore, descriptions of the operation 1810 are omitted for brevity.

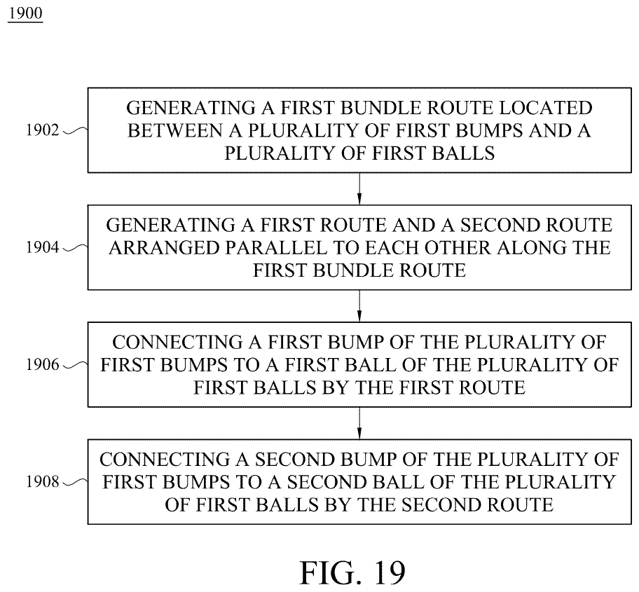

FIG. 19 is a flowchart diagram of a method 1900 designing the semiconductor device 100 described above, in accordance with some embodiments of the present disclosure. As illustratively shown in FIG. 19, the method 1900 includes operations 1902, 1904, 1906 and 1908.

At the operation 1902, a first bundle route located between a plurality of first bumps and a plurality of first balls is generated. For example, the bundle BR1 located between the bumps C1-C3 and the balls B1-B3 is generated.

At the operation 1904, a first route and a second route arranged parallel to each other along the first bundle route is generated. For example, the route DR1 and the route DR2 arranged parallel to each other along the bundle route BR1 is generated.

At the operation 1906, a first bump of the plurality of first bumps is connected to a first ball of the plurality of first balls by the first route. For example, the bump C1 of the bumps C1-C3 is connected to the ball B1 of the balls B1-B3 by the route DR1.

At the operation 1908, a second bump of the plurality of first bumps is connected to a second ball of the plurality of first balls by the second route. For example, the bump C2 of the bumps C1-C3 is connected to the ball B2 of the balls B1-B3 by the route DR2. In some embodiments, the first route is separated from the second route. For example, the route DR1 is separated from the route DR2.

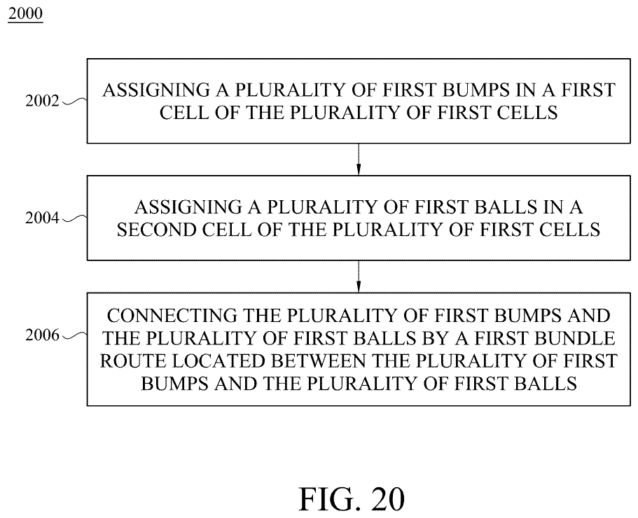

FIG. 20 is a flowchart diagram of a method 2000 designing the semiconductor device 100 described above, in accordance with some embodiments of the present disclosure. As illustratively shown in FIG. 20, the method 2000 includes operations 2002, 2004 and 2006.

At the operation 2002, a plurality of first bumps are assigned in a first cell of a plurality of first cells. For example, the bumps C1-C3 are assigned in the G-cell G13 of the G-cells 600.

At the operation 2004, a plurality of first balls are assigned in a second cell of the plurality of first cells. For example, the balls B1-B3 are assigned in the G-cell G41 of the G-cells 600.

At the operation 2006, the plurality of first bumps and the plurality of first balls are connected by a first bundle route located between the plurality of first bumps and the plurality of first balls. For example, the bumps C1-C3 and the balls B1-B3 are connected by the bundle route BR91 located between the bumps C1-C3 and the balls B1-B3.

In some embodiments, the first bundle route crosses over and is perpendicular to each of a first edge of the first cell and a first edge of the second cell. For example, the bundle route BR91 crosses over and is perpendicular to each of the edge of the G-cell G13 and the edge of the G-cell G41.

FIG. 21 is a block diagram of an electronic design automation (EDA) system 2100 for designing the semiconductor device 100 described above, in accordance with some embodiments of the present disclosure. The EDA system 2100 is configured to implement one or more operations of the method disclosed above. In some embodiments, the EDA system 2100 includes an automatic placement and routing (APR) system.

In some embodiments, the EDA system 2100 is a general purpose computing device including a hardware processor 2120 and a non-transitory, computer-readable storage medium 2160. The storage medium 2160, amongst other things, is encoded with, i.e., stores, computer program code (instructions) 2161, i.e., a set of executable instructions. Execution of the instructions 2161 by the hardware processor 2120 represents (at least in part) an EDA tool which implements a portion or all of methods including, for example, the method disclosed above.

The processor 2120 is electrically coupled to the computer-readable storage medium 2160 via a bus 2150. The processor 2120 is also electrically coupled to an I/O interface 2110 and a fabrication tool 2170 by the bus 2150. A network interface 2130 is also electrically connected to the processor 2120 via the bus 2150. The network interface 2130 is connected to a network 2140, and thus that the processor 2120 and the computer-readable storage medium 2160 are capable of connecting to external elements via the network 2140. The processor 2120 is configured to execute the computer program code 2161 encoded in the computer-readable storage medium 2160 in order to cause the EDA system 2100 to be usable for performing a portion or all of the noted processes and/or methods. In one or more embodiments, the processor 2120 is a central processing unit (CPU), a multi-processor, a distributed processing system, an application specific integrated circuit (ASIC), and/or a suitable processing unit.

In one or more embodiments, the computer-readable storage medium 2160 is an electronic, magnetic, optical, electromagnetic, infrared, and/or a semiconductor system (or apparatus or device). For example, the computer-readable storage medium 2160 includes a semiconductor or solid-state memory, a magnetic tape, a removable computer diskette, a random access memory (RAM), a read-only memory (ROM), a rigid magnetic disk, and/or an optical disk. In one or more embodiments using optical disks, the computer-readable storage medium 2160 includes a compact disk-read only memory (CD-ROM), a compact disk-read/write (CD-R/W), and/or a digital video disc (DVD).

In one or more embodiments, the storage medium 2160 stores the computer program code 2161 configured to cause the EDA system 2100 (where such execution represents (at least in part) the EDA tool) to be usable for performing a portion or all of the noted processes and/or methods. In one or more embodiments, the storage medium 2160 also stores information which facilitates performing a portion or all of the noted processes and/or methods. In one or more embodiments, the storage medium 2160 stores a library 2162 of standard cells including such standard cells as disclosed herein.

In one or more embodiments, the storage medium 2160 stores layout diagrams 2164 which, for example, correspond to the semiconductor device 100. In one or more embodiments, the storage medium 2160 stores a pattern data farm 2165.

In one or more embodiments, the storage medium 2160 is a memory which store computer program codes. The computer program codes correspond to the operations described above and configured to be executed by the processor 2120. In one or more embodiments, the processor 2120 is configured to execute the computer program codes in the memory to: generate a first bundle route (e.g., the bundle route BR1) located between a plurality of first bumps (e.g., the bumps C1-C3) and a plurality of first balls (e.g., the balls B1-B3), generate a first route (e.g., the route DR1) and a second route (e.g., the route DR2) arranged parallel to each other along the first bundle route, connect a first bump (e.g., the bump C1) of the plurality of first bumps to a first ball (e.g., the ball B1) of the plurality of first balls by the first route, and connect a second bump (e.g., the bump C2) of the plurality of first bumps to a second ball (e.g., the ball B2) of the plurality of first balls by the second route. In some embodiments, the first route is separated from the second route.

The EDA system 2100 includes an I/O interface 2110. The I/O interface 2110 is coupled to external circuitry. In one or more embodiments, The I/O interface 2110 includes a keyboard, keypad, mouse, trackball, trackpad, touchscreen, and/or cursor direction keys for communicating information and commands to the processor 2120.

The EDA system 2100 also includes the network interface 2130 coupled to the processor 2120. The network interface 2130 allows the EDA system 2100 to communicate with the network 2140, to which one or more other computer systems are connected. The network interface 2130 includes wireless network interfaces such as BLUETOOTH, WIFI, WIMAX, GPRS, or WCDMA; or wired network interfaces such as ETHERNET, USB, or IEEE-12164. In one or more embodiments, a portion or all of noted processes and/or methods including, for example, the method described above, is implemented in two or more systems including the EDA system 2100.

The EDA system 2100 also includes the fabrication tool 2170 coupled to the processor 2120. The fabrication tool 2170 is configured to fabricate chips corresponding to layouts, including, for example, the semiconductor device 100 described above, based on the design files processed by the processor 2120 and/or the IC layout designs as discussed above.

The EDA system 2100 is configured to receive information through the I/O interface 2110. The information received through the I/O interface 2110 includes one or more of instructions, data, design rules, libraries of standard cells, and/or other parameters for processing by the processor 2120. The information is transferred to the processor 2120 via the bus 2150. The EDA system 2100 is configured to receive information related to a UI through the I/O interface 2110. The information is stored in the computer-readable medium 2160 as a user interface (UI) 2163.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by the EDA system 2100. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, for example, one or more of an optical disk, such as a DVD, a magnetic disk, such as a hard disk, a semiconductor memory, such as a ROM, a RAM, a memory card, and the like.

In some embodiments, routes are implemented by conductive materials, such as metal lines. Bumps and balls are in different layers and are electrically connected to each other through routes. Bumps and balls are in different layers. The size of a bump is smaller than the size of a ball. Global-cells (G-cells) are generated through EDA tools. A net is a line electrically connecting a ball to a bump. The circuit CI1 is implemented by a central processing unit (CPU). A blockage is implemented by a CPU component, a hardware, an obstacle, a route or the like.

In some approaches, some electronic design automation (EDA) routers route all nets directly. However, sequential net-by-net routing often results in poor routing quality. As a result, the space of the redistribution layer (RDL) is wasted. In addition, routing manually leads to lack of efficiency.

Compared to above approaches, in some embodiments of present disclosure, the bundle route BR1 over G-cells 600 is created according to edge capacities of the edges E81-E83 of the G-cell 800, such that the routes DR1 and DR2 are generated along the bundle route BR1 over G-cells 600. As a result, the routing quality is improved, and the cycle time is shortened.

Also disclosed is a structure. The structure includes at least one ball, at least one bump and at least one route. The at least one route is configured to couple the at least one ball to the at least one bump. The at least one route comprises a plurality of first route edges and a plurality of second route edges, and an angle between one of plurality of first route edges and one of plurality of second route edges is approximately equal to an angle between another one of plurality of first route edges and another one of plurality of second route edges.

Also disclosed is a method. The method includes: forming a plurality of balls; forming a routing layer above the plurality of balls; and forming a plurality of bumps above the routing layer. Forming the routing layer comprises: forming a plurality of routes coupling the plurality of balls to the plurality of bumps. Angles of the plurality of routes are approximately equal to each other.

Also disclosed is a system. The system includes a memory and a processor. The memory is configured to store computer program codes. The processor is configured to execute the computer program codes in the memory to: generate a first bundle route located between a plurality of first bumps and a plurality of first balls; generate a first route and a second route arranged parallel to each other along the first bundle route; connect a first bump of the plurality of first bumps to a first ball of the plurality of first balls by the first route; and connect a second bump of the plurality of first bumps to a second ball of the plurality of first balls by the second route. The first route is separated from the second route.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
at least one ball;
at least one bump; and
at least one route configured to couple the at least one ball to the at least one bump,
wherein the at least one route comprises a plurality of first route edges and a plurality of second route edges, and
an angle between one of plurality of first route edges and one of plurality of second route edges is approximately equal to an angle between another one of plurality of first route edges and another one of plurality of second route edges.

2. The structure of claim 1, wherein the at least one route is contained in a bundle route,
the at least one route only comprises one route, and
the one route is configured to couple one of the at least one ball to one of the at least one bump.

3. The structure of claim 1, wherein the at least one route comprises:
a first route configured to couple a first ball of the at least one ball to a first bump of the at least one bump; and
a second route configured to couple a second ball of the at least one ball to a second bump of the at least one bump,
wherein the first route has a first route edge and a second route edge,
the second route has a third route edge and a fourth route edge, and
an angle between the first route edge and the second route edge is approximately equal to an angle between the third route edge and the fourth route edge.

4. The structure of claim 3, wherein
the first route further has a fifth route edge,
the second route further has a sixth route edge, and
an angle between the fifth route edge and the second route edge is approximately equal to an angle between the sixth route edge and the fourth route edge.

5. The structure of claim 3, wherein a distance between the first route edge and the third route edge is shorter than or close to each of widths of the least one route.

6. The structure of claim 3, wherein the at least one route further comprises:
a third route configured to couple a third ball of the at least one ball to a third bump of the at least one bump,
wherein the third route has a seventh route edge and an eighth route edge, and
the angle between the first route edge and the second route edge is approximately equal to an angle between the seventh route edge and the eighth route edge.

7. The structure of claim 6, wherein the second route further has a ninth route edge opposite to the third route edge, and
a distance between the ninth route edge and the seventh route edge is shorter than or close to each of widths of the least one route.

8. A method, comprising:
forming a plurality of balls;
forming a routing layer above the plurality of balls; and
forming a plurality of bumps above the routing layer,
wherein forming the routing layer comprises:
forming a plurality of routes coupling the plurality of balls to the plurality of bumps,
wherein angles of the plurality of routes are approximately equal to each other.

9. The method of claim 8, wherein forming the plurality of routes comprises:
forming a first route coupling a first ball of the plurality of balls to a first bump of the plurality of bumps; and
forming a second route coupling a second ball of the plurality of balls to a second bump of the plurality of bumps,
wherein the first route has a first route edge and a second route edge,
the second route has a third route edge and a fourth route edge, and
an angle between the first route edge and the second route edge is approximately equal to an angle between the third route edge and the fourth route edge.

10. The method of claim 9, wherein forming the plurality of routes further comprises:
forming a third route coupling a third ball of the plurality of balls to a third bump of the plurality of bumps,
wherein the second route further has a fifth route edge and a sixth route edge,
the third route has a seventh route edge and an eighth route edge, and
an angle between the fifth route edge and the sixth route edge is approximately equal to an angle between the seventh route edge and the eighth route edge.

11. The method of claim 9, wherein a distance between the first route edge and the third route edge is shorter than or close to each of widths of the plurality of routes.

12. A system, comprising:
a memory configured to store computer program codes; and
a processor configured to execute the computer program codes in the memory to:
generate a first bundle route located between a plurality of first bumps and a plurality of first balls;
generate a first route and a second route arranged parallel to each other along the first bundle route;
connect a first bump of the plurality of first bumps to a first ball of the plurality of first balls by the first route; and
connect a second bump of the plurality of first bumps to a second ball of the plurality of first balls by the second route,
wherein the first route is separated from the second route.

13. The system of claim 12, wherein the processor is further configured to assign the plurality of first bumps to a first cell of a plurality of first cells, and further configured to assign the first bundle route to a first edge of the first cell when an edge capacity of the first edge of the first cell is more than or equal to a number of nets demanded by the first bundle route.

14. The system of claim 13, wherein the edge capacity of the first edge is calculated according to each of a length of the first edge, a width of the first route and a space between the first route and the second route.

15. The system of claim 12, wherein the processor is further configured to assign the first bundle route to at least a first edge of a first cell and a first edge of a second cell adjacent to the first cell when a number of nets demanded by the first bundle route is more than an edge capacity of the first edge of the first cell.

16. The system of claim 12, wherein the processor is further configured to generate a congestion map with a plurality of global cells, and
the congestion map shows and assess route feasibility.

17. The system of claim 16, wherein the plurality of global cells are octagon shaped for 0-degree, 45-degree, 90-degree and 135-degree angle route planning.

18. The system of claim 16, wherein the plurality of global cells have flexible polygon-style.

19. The system of claim 16, wherein the plurality of global cells have a multi-layers structure.

20. The system of claim 16, wherein when a route demand is larger than or equal to a global cell edge capacity, an overflow information is shown in the congestion map.
